(19) United States
(12) Patent Application Publication
(10) Pub. No.: US 2025/0234590 A1
(43) Pub. Date: Jul. 17, 2025

(54) THREE-DIMENSIONAL SEMICONDUCTOR DEVICE AND METHOD OF MANUFACTURING THE SAME

(71) Applicant: Samsung Electronics Co., Ltd., Suwon-si (KR)

(72) Inventors: JIN-WOOK YANG, Suwon-si (KR); SUNGIL PARK, Suwon-si (KR); JAE HYUN PARK, Suwon-si (KR); YOSHINAO HARADA, Suwon-si (KR)

(21) Appl. No.: 18/943,194

(22) Filed: Nov. 11, 2024

(30) Foreign Application Priority Data
Jan. 16, 2024 (KR) 10-2024-0006937

(51) Int. Cl. H01L 29/417; H01L 21/822; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017; H10D 84/0186; H10D 84/038; H10D 84/856; H10D 88/01

(57) ABSTRACT

A three-dimensional semiconductor device includes a backside metal layer, a lower channel pattern and an upper channel pattern sequentially provided on the backside metal layer, a gate electrode crossing the lower and upper channel patterns in a first direction, and including a first gate electrode and a second gate electrode adjacent to each other in the first direction, a separation insulating pattern between the first and second gate electrodes, and a conductive plate extending in the separation insulating pattern in each of a second direction intersecting the first direction and a third direction perpendicular to the first direction, wherein the conductive plate includes a first conductive plate and a second conductive plate adjacent to each other in the first direction in the separation insulating pattern.

### CROSS-REFERENCE TO RELATED APPLICATIONS

This U.S. non-provisional patent application claims priority under 35 U.S.C. § 119 to Korean Patent Application No. 10-2024-0006937 filed on Jan. 16, 2024, in the Korean Intellectual Property Office, the entire contents of which are hereby incorporated by reference.

### BACKGROUND OF THE INVENTION

The inventive concept relates to a three-dimensional semiconductor device and a method of manufacturing the same, and more particularly, relates to a three-dimensional semiconductor device including a field effect transistor and a method of manufacturing the same.

A semiconductor device may include an integrated circuit including metal-oxide-semiconductor field effect transistors (MOSFET). As sizes and design rules of semiconductor devices have been reduced, sizes of MOSFET have also been scaled down. Operating characteristics of semiconductor devices may be deteriorated by the scale down of the MOSFET. Thus, various researches are being conducted for semiconductor devices capable of overcoming limitations caused by a high integration and of improving performance.

### SUMMARY

An object of the inventive concept is to provide a three-dimensional semiconductor device with improved integration and a method of manufacturing the same.

An object of the inventive concept is to provide a three-dimensional semiconductor device with improved electrical characteristics and productivity and a method of manufacturing the same.

The problem to be solved by the inventive concept is not limited to the problems mentioned above, and other problems not mentioned will be clearly understood by those skilled in the art from the description below.

A three-dimensional semiconductor device according to some embodiments of the inventive concept includes a backside metal layer, first lower channel patterns and first upper channel patterns sequentially provided on the backside metal layer; first gate electrodes crossing the first lower channel patterns and the first upper channel patterns; second gate electrodes being adjacent to the first gate electrodes in a first direction; a separation insulating pattern between the first and second gate electrodes; a first conductive plate extending in the separation insulating pattern in each of a second direction and a third direction; and a second conductive plate extending in the separation insulating pattern in each of the second direction and the third direction. The second conductive plate is adjacent to the first conductive plate in the first direction. The first conductive plate and the second conductive plate are separated from each other.

A three-dimensional semiconductor device according to some embodiments of the inventive concept includes a backside metal layer, first lower channel patterns and first upper channel patterns sequentially provided on the backside metal layer; second lower channel patterns and second upper channel patterns sequentially provided on the backside metal layer, first gate electrodes crossing the first lower channel patterns and the first upper channel patterns; and second gate electrodes crossing the second lower channel patterns and the second upper channel patterns. The second gate electrodes are adjacent to the first gate electrodes in a first direction. The three-dimensional semiconductor device further includes a separation insulating pattern between the first and second gate electrodes; and a first conductive plate extending in the separation insulating pattern in each of a second direction and a third direction. The first conductive plate is adjacent to the first gate electrodes. The three-dimensional semiconductor device further includes a second conductive plate extending in the separation insulating pattern in each of the second direction and the third direction. The second conductive plate is adjacent to the second gate electrodes. The first conductive plate and the second conductive plate are separate from each other. The first, second and third second directions are perpendicular to each other.

A three-dimensional semiconductor device according to some embodiments of the inventive concept includes a backside metal layer first lower channel patterns and first upper channel patterns sequentially provided on the backside metal layer; second lower channel patterns and second upper channel patterns sequentially provided on the backside metal layer; first gate electrodes crossing the first lower channel patterns and the first upper channel patterns; second gate electrodes crossing the second lower channel patterns and the second upper channel patterns, the second gate electrodes being adjacent to the first gate electrodes in a first direction; a separation insulating pattern between the first and second gate electrodes; a first conductive plate extending in the separation insulating pattern in each of a second direction and a third direction, the first conductive plate being adjacent to the first gate electrodes; and a second conductive plate extending in the separation insulating pattern in each of the second direction and the third direction. The second conductive plate being adjacent to the first gate electrodes. The first conductive plate and the second conductive plate are separate from each other. The first, second and third second directions are perpendicular to each other.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a logic cell of a semiconductor device according to a comparative example of the inventive concept.

FIG. 2 is a plan view of a logic cell of a semiconductor device according to embodiments of the inventive concept.

FIG. 3 is a plan view for explaining a three-dimensional semiconductor device according to some embodiments of the inventive concept.

FIG. 4 is an enlarged view corresponding to portion ‘P1’ in FIG. 3.

FIGS. 5A to 5E are cross-sectional views taken along lines A-A′, B-B′, C-C′, E-E′, and F-F′ of FIG. 3, respectively.

FIG. 6 is a cross-sectional view taken along line B-B′ of FIG. 3.

FIG. 7 is an enlarged view corresponding to portion ‘P1’ in FIG. 3.

FIGS. 8A to 8D are cross-sectional views taken along lines B-B′, D-D′, E-E′, and F-F′ of FIG. 3, respectively.

FIG. 9 is an enlarged view corresponding to portion ‘P1’ in FIG. 3.

FIGS. 10A to 10D are cross-sectional views taken along lines B-B′, D-D′, E-E′, and F-F′ of FIG. 3, respectively.

FIGS. 11A, 11B, 12A to 12C, 13A, 13B, 14A to 14C, 15A and 15B are cross-sectional views for explaining a method of manufacturing a three-dimensional semiconductor device according to embodiments of the inventive concept.

FIGS. 16 and 17 are cross-sectional views for explaining a method of manufacturing a three-dimensional semiconductor device according to embodiments of the inventive concept.

### DETAILED DESCRIPTION

Hereinafter, in order to explain the inventive concept in detail, embodiments according to the inventive concept will be described with reference to the accompanying drawings. It should be noted that items described in the singular herein, may be provided in plural, as can be seen in the various figures from the context in which they are described, and such description should be considered applicable to each of the plural, unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

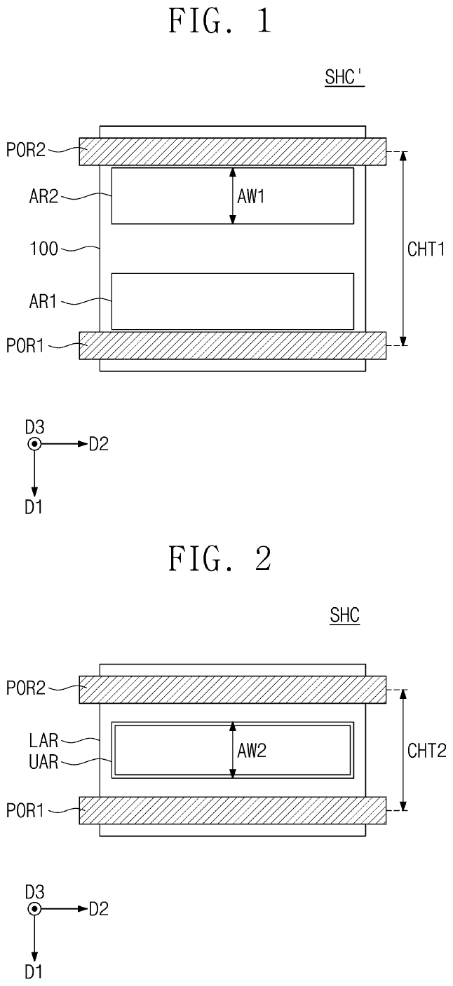

FIG. 1 is a plan view of a logic cell of a semiconductor device according to a comparative example of the inventive concept.

Referring to FIG. 1, a single height cell SHC′ may be provided. As is conventional, a single height cell refers to a cell that fits within a single row of a standard cell layout in a plan view (thus, “height” in a single height cell refers to row height and does not refer to the dimension typically considered vertical (i.e., perpendicular to the surface of the substrate). In detail, a first power line POR1 and a second power line POR2 may be provided on a substrate 100. A drain voltage (VDD), for example, a power voltage, may be applied to one of the first power line POR1 or the second power line POR2. A source voltage (VSS), for example, a ground voltage, may be applied to the other one of the first power line POR1 and the second power line POR2. As an example, the first power line POR1 and the second power line POR2 may be spaced apart from each other in a first direction D1 parallel to a lower surface of the substrate 100, and may be parallel to the lower surface of the substrate 100. Each may extend in a second direction D2 that intersects the first direction D1.

The single height cell SHC′ may be defined between the first power line POR1 and the second power line POR2. The single height cell SHC′ may include a first active region AR1 and a second active region AR2. One of the first active region AR1 and the second active region AR2 may be a p-type MOSFET (PMOSFET) region, and the other one of the first active region AR1 and the second active region AR2 may be an n-type MOSFET (NMOSFET) region. For example, the single height cell SHC′ may have a CMOS (Complementary Metal-Oxide Semiconductor) structure provided between the first power line POR1 and the second power line POR2.

A semiconductor device according to the comparative example may be a two-dimensional device in which transistors of a front-end-of-line (FEOL) layer are arranged two-dimensionally. For example, the NMOSFET on the first active region AR1 may be formed spaced apart in a first direction D1 from the PMOSFET on the second active region AR2.

Each of the first active region AR1 and the second active region AR2 may have a first width AW1 in the first direction D1. A length of the single height cell SHC′ according to the comparative example in the first direction D1 may be defined as a first height CHT1. The first height CHT1 may be substantially equal to a distance (e.g., pitch) between the first power line POR1 and the second power line POR2.

A single height cell SHC′ may constitute one logic cell. In this description, a logic cell may refer to a logic element (e.g., AND, OR, XOR, XNOR, inverter, etc.) that performs a specific function. For example, the logic cell may include transistors for constituting a logic element and wiring lines that connect the transistors to each other.

Because a two-dimensional device is included in the single height cell SHC′ according to the comparative example, the first active region AR1 and the second active region AR2 may be disposed spaced apart from each other in the first direction D1 without overlapping each other. Therefore, it may be required that the first height CHT1 of the single height cell SHC′ be defined to include all of the first and second active regions AR1 and AR2 that are spaced apart from each other in the first direction D1. For example, the first height CHT1 of the single height cell SHC′ may have a size that encompasses at least two first widths AW1. As a result, the first height CHT1 of the single height cell SHC′ according to the comparative example may be required to become relatively large. Therefore, the single height cell SHC′ according to the comparative example may have a relatively large area.

FIG. 2 is a plan view of a logic cell of a semiconductor device according to embodiments of the inventive concept.

Referring to FIG. 2, a single height cell SHC including a three-dimensional device (e.g., a stacked transistor) may be provided. Specifically, a first power line POR1 and a second power line POR2 may be provided on a substrate 100. A single height cell SHC may be defined between the first power line POR1 and the second power line POR2.

A single height cell SHC may include a lower active region LAR and an upper active region UAR. One of the lower active region LAR and the upper active region UAR may be a PMOSFET region, and the other one of the lower active region LAR and the upper active region UAR may be an NMOSFET region.

The semiconductor device according to the present embodiment may be a three-dimensional device, and transistors of a FEOL layer may be vertically stacked. For example, the lower active region LAR may be provided as a part of a bottom tier of the FEOL layer on the substrate 100, and the upper active region UAR may be stacked on the lower active region LAR as a part of a top tier of the FEOL layer. For example, a PMOSFET in the lower active region LAR may be provided on the substrate 100, and an NMOSFET in the upper active region UAR may be stacked on the PMOSFET. The lower active region LAR and the upper active region UAR may be spaced apart from each other in a vertical direction, for example, in a third direction D3 perpendicular to a lower surface of the substrate 100.

Each of the lower active region LAR and the upper active region UAR may have a second width AW2 in the first direction D1. A length of the single height cell SHC in the first direction D1 according to the present embodiment may be defined as a second height CHT2.

Because the single height cell SHC according to the present embodiment includes a three-dimensional element, for example, a stacked transistor, the lower active region LAR and the upper active region UAR may vertically overlap each other. Accordingly, the second height CHT2 of the single height cell SHC may have a size that encompasses one second width AW2 described above. As a result, the second height CHT2 of the single height cell SHC according to the present embodiment may be smaller than the first height CHT1 of the single height cell SHC′ of FIG. 1 described above. For example, the area of the single height cell SHC according to the present embodiment may be relatively small. The area of the logic cell may be reduced, thereby improving integration of the three-dimensional semiconductor device according to the present embodiment.

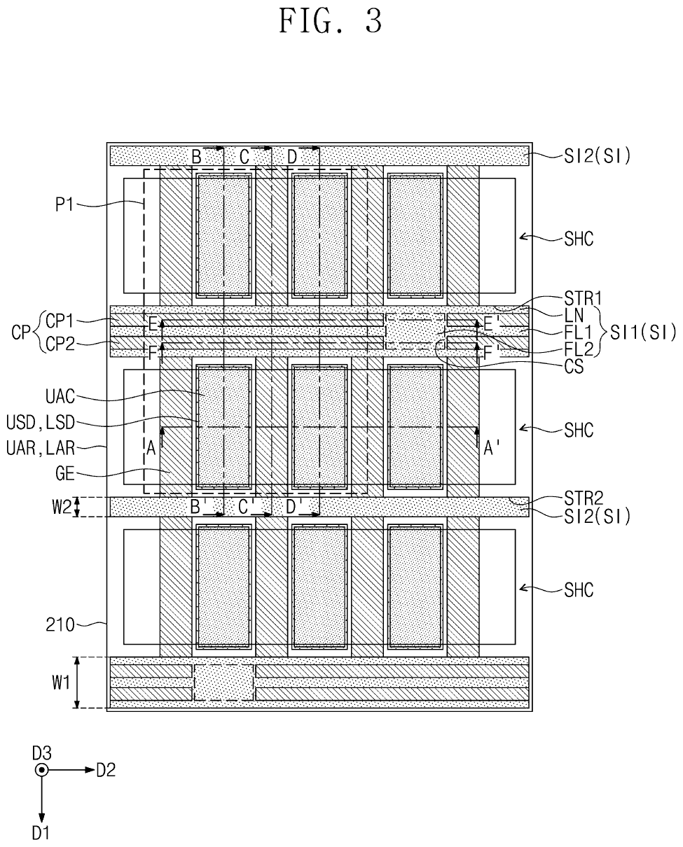

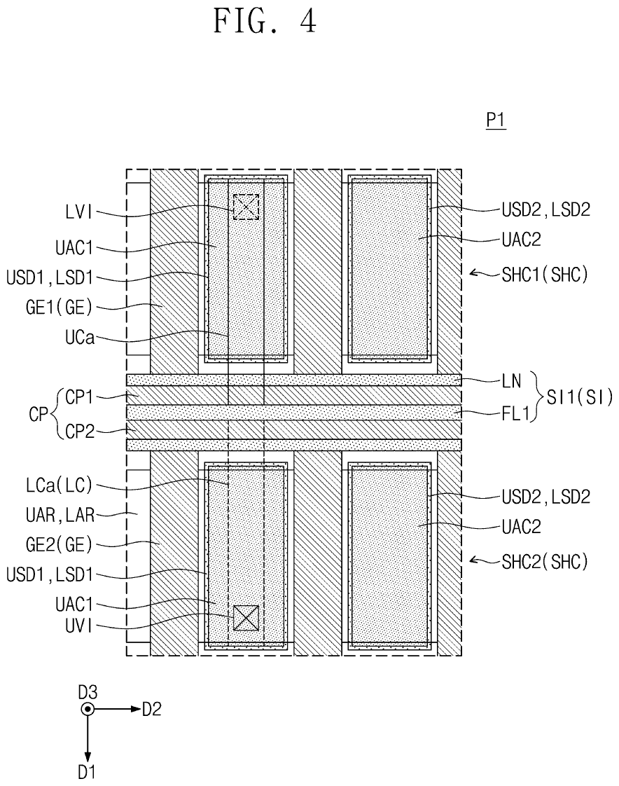

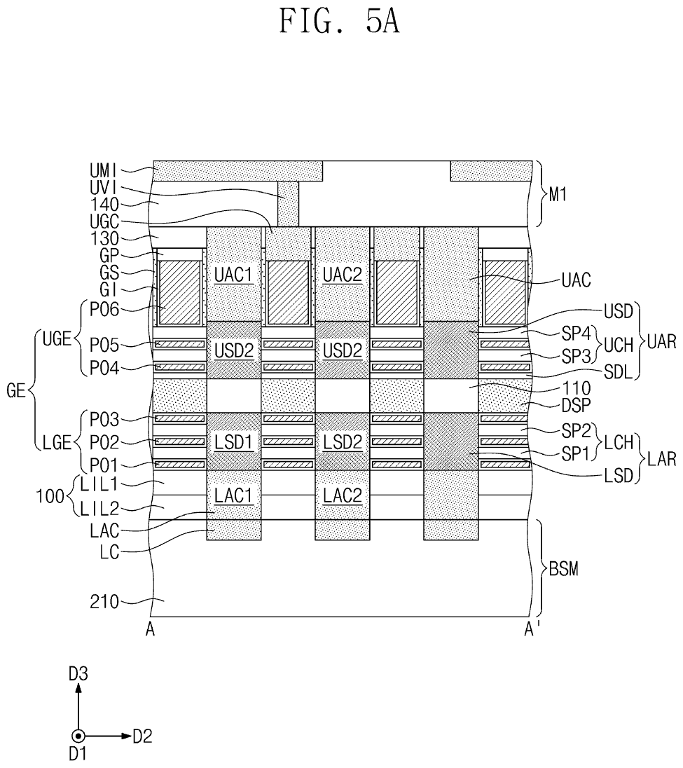

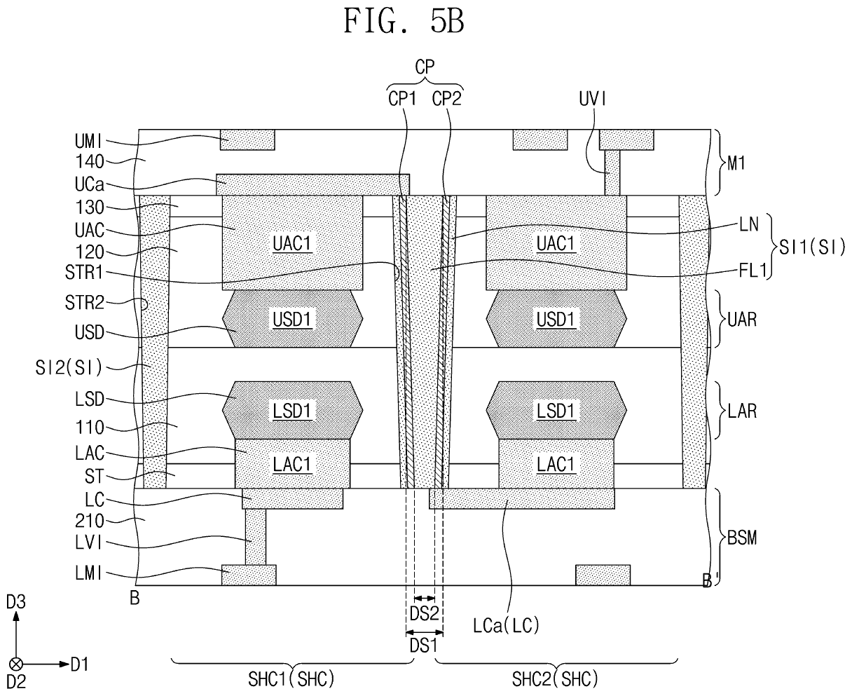

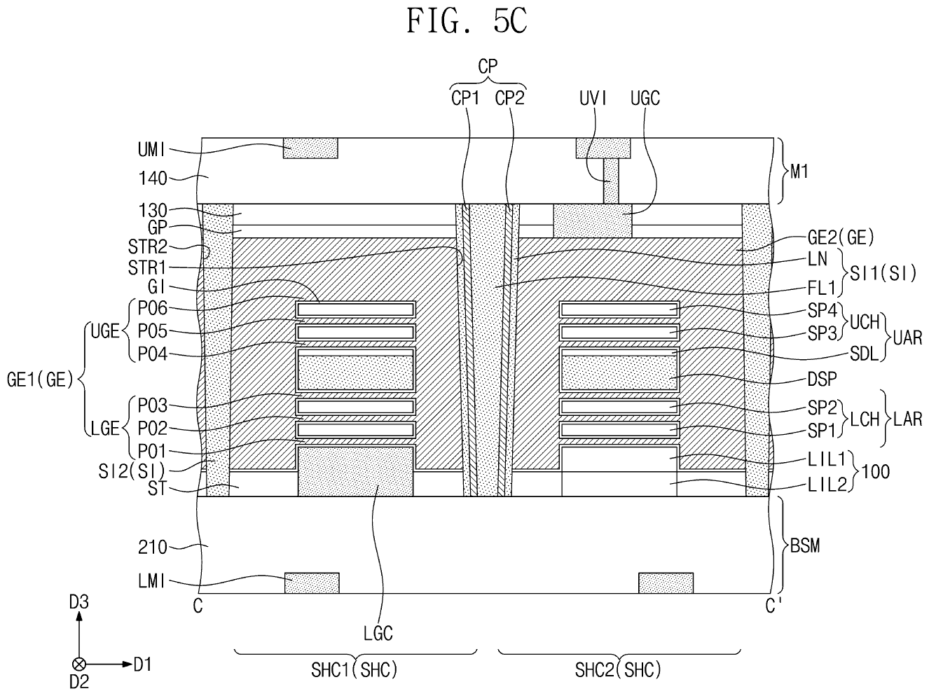

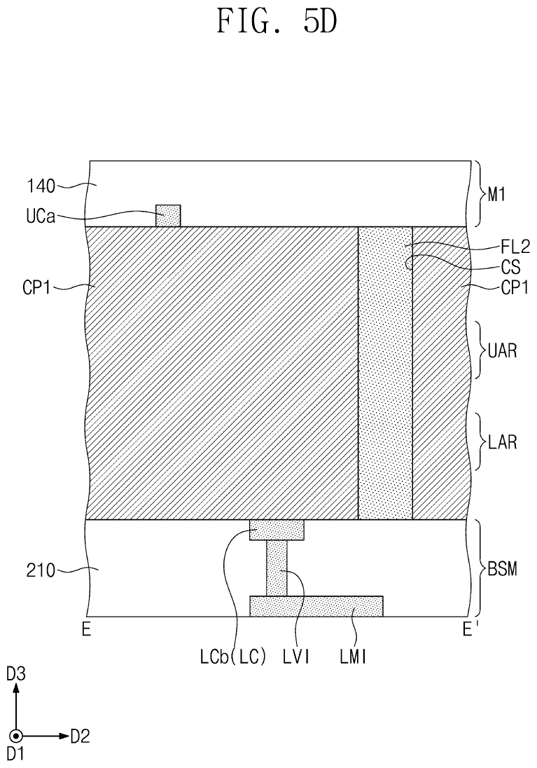

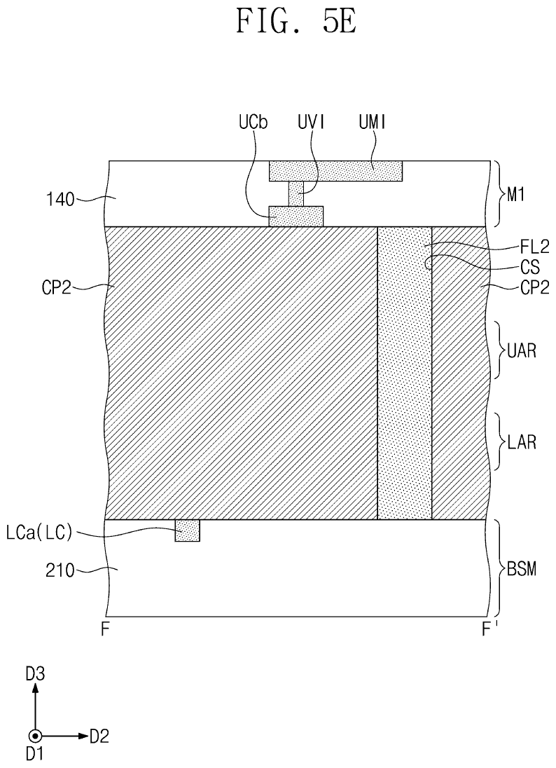

FIG. 3 is a plan view for explaining a three-dimensional semiconductor device according to some embodiments of the inventive concept. FIG. 4 is an enlarged view corresponding to portion ‘P1’ in FIG. 3. FIGS. 5A to 5E are cross-sectional views taken along lines A-A′, B-B′, C-C′, E-E′, and F-F′ of FIG. 3, respectively.

Referring to FIGS. 3, 4, and 5A to 5E, single height cells SHC may be provided on a substrate 100. In one embodiment of the inventive concept, the substrate 100 may be an insulating substrate including a silicon-based insulating material (e.g., silicon oxide and/or silicon nitride). In another embodiment of the inventive concept, the substrate 100 may be a semiconductor substrate containing silicon, germanium, silicon germanium, and so forth.

As an example, the substrate 100 may include a first lower insulating layer LIL1 and a second lower insulating layer LIL2. The first lower insulating layer LIL1 may be provided on the second lower insulating layer LIL2. The first lower insulating layer LIL1 may include a silicon-based insulating material (e.g., silicon oxide) and/or a semiconductor material (e.g., Si or SiGe). The second lower insulating layer LIL2 may include a silicon-based insulating material (e.g., silicon oxide, silicon oxynitride, or silicon nitride).

A device isolation layer ST may be provided on a backside metal layer BSM. The device isolation layer ST may define an area for lower source drain patterns LSD of the single height cell SHC. The device isolation layer ST may be interposed between the backside metal layer BSM and a first interlayer insulating layer 110, both of which will be described later. As an example, the device isolation layer ST may include a silicon-based insulating material (e.g., silicon oxide, silicon oxynitride, or silicon nitride).

In one embodiment of the inventive concept, each single height cell SHC may be a logic cell constituting a logic circuit (e.g., a logic gate, such as a NAND, OR, XOR, NOT (an inverter), NAND, NOR, or an XNOR gate). Each single height cell SHC may be a logic cell including the three-dimensional element described above with reference to FIG. 2. The single height cells SHC may be repeatedly arranged in the first direction D1.

Each single height cell SHC may include a lower active region LAR and an upper active region UAR sequentially stacked on the substrate 100. One of the lower and upper active regions LAR and UAR may be a PMOSFET region, and the other of the lower and upper active regions LAR and UAR may be an NMOSFET region. The lower active region LAR may be provided as a part of a bottom tier of the FEOL layer, and the upper active region UAR may be provided as a part of a top tier of the FEOL layer. “A bottom tier of a FEOL layer” or “a lower tier of a three-dimensional device” may refer to lower channel patterns LCH and upper source drain patterns LSD, which are described later. Also, “a top tier of a FEOL layer” or “an upper tier of a three-dimensional device” may refer to upper channel patterns UCH and upper source drain patterns USD, which are described later. The NMOSFET and PMOSFET of the lower and upper active regions LAR and UAR may be vertically stacked to form a three-dimensional stacked transistor. For example, the lower active region LAR may be a PMOSFET region, and the upper active region UAR may be an NMOSFET region. Each of the lower and upper active regions LAR and UAR may have a bar shape or a line shape extending in the second direction D2.

The lower active region LAR may include lower channel patterns LCH and lower source drain patterns LSD. The lower channel pattern LCH may be interposed between a pair of lower source drain patterns LSD along the second direction. The lower channel pattern LCH may electrically connect a pair of lower source drain patterns LSD to each other.

The lower channel pattern LCH may include a first semiconductor pattern SP1 and a second semiconductor pattern SP2 that are stacked and spaced apart from each other, but the number of semiconductor pattern is not limited thereto. For example, the lower channel pattern LCH may further include one or more additional semiconductor patterns that are stacked and spaced apart from the second semiconductor pattern SP2. Each of the first and second semiconductor patterns SP1 and SP2 may include silicon (Si), germanium (Ge), or silicon germanium (SiGe). Preferably, each of the first and second semiconductor patterns SP1 and SP2 may include crystalline silicon. Each of the first and second semiconductor patterns SP1 and SP2 may be in the form of a nanowire, nanoribbon or nanosheet.

The lower source drain patterns LSD may be provided on the substrate 100. Each lower source drain pattern LSD may be an epitaxial pattern formed through a selective epitaxial growth (SEG) process.

The lower source drain patterns LSD may be doped with impurities to have a first conductivity type. The first conductivity type may be N-type or P-type. In the present embodiment, the first conductivity type may be P type. The lower source drain patterns LSD may include silicon (Si) and/or silicon germanium (SiGe).

A first interlayer insulating layer 110 may be provided on the lower source drain pattern LSD. The first interlayer insulating layer 110 may cover the lower source drain patterns LSD.

A lower active contact LAC may be provided below the lower source drain pattern LSD. The lower active contact LAC may be electrically connected to the lower source drain pattern LSD. Components described herein as being “electrically connected” are configured such that an electrical signal can be transferred from one component to the other (although such electrical signal may be attenuated in strength as it is transferred and may be selectively transferred). The lower active contact LAC may be buried in the substrate 100. For example, the area where the lower active contact LAC is formed may be confined to the recess of the substrate 100. The lower active contact LAC may include a conductive material such as metal.

The upper active region UAR may be provided on the first interlayer insulating layer 110. The upper active region UAR may include upper channel patterns UCH and upper source drain patterns USD. The upper channel patterns UCH may vertically overlap the lower channel patterns LCH. The upper source drain patterns USD may vertically overlap the lower source drain patterns LSD. The upper channel pattern UCH may be interposed between a pair of upper source drain patterns USD. The upper channel pattern UCH may electrically connect a pair of upper source drain patterns USD to each other.

The upper channel pattern UCH may include a third semiconductor pattern SP3 and a fourth semiconductor pattern SP4 that are stacked and spaced apart from each other, but the number of semiconductor pattern is not limited thereto. As an example, the upper channel pattern UCH may further include one or more additional semiconductor patterns stacked while being spaced apart from the fourth semiconductor pattern SP4. The third and fourth semiconductor patterns SP3 and SP4 of the upper channel pattern UCH may include the same semiconductor material as the first and second semiconductor patterns SP1 and SP2 of the lower channel pattern LCH described above. Each of the third and fourth semiconductor patterns SP3 and SP4 may be in the form of a nanowire, nanoribbon or nanosheet.

At least one dummy channel pattern DSP may be interposed between the lower channel pattern LCH and the upper channel pattern UCH. A seed layer SDL may be interposed between the dummy channel pattern DSP and the upper channel pattern UCH. The dummy channel pattern DSP may be spaced apart from the lower and upper source drain patterns LSD and USD. For example, the dummy channel pattern DSP may not be connected to any source drain pattern. The dummy channel pattern DSP may include a semiconductor material such as silicon (Si), germanium (Ge), or silicon germanium (SiGe), or may include a silicon-based insulating material such as a silicon oxide or silicon nitride layer. In one embodiment of the inventive concept, the dummy channel pattern DSP may include the silicon-based insulating material.

The upper source drain patterns USD may be provided on an upper surface of the first interlayer insulating layer 110. Each of the upper source drain patterns USD may be an epitaxial pattern formed through a selective epitaxial growth (SEG) process.

The upper source drain patterns USD may be doped with impurities to have a second conductivity type. The second conductivity type may be different from the first conductivity type of the lower source drain pattern LSD. The second conductivity type may be N-type. The upper source drain patterns USD may include silicon germanium (SiGe) and/or silicon (Si).

A plurality of gate electrodes GE may be provided on the stacked lower and upper channel patterns LCH and UCH. When viewed in a plan view, the gate electrode GE may have a bar shape extending in the first direction D1. The gate electrode GE may vertically overlap the stacked lower and upper channel patterns LCH and UCH and may cross the stacked lower and upper channel patterns LCH and UCH in the first direction D1. For example, in a plan view, the plurality of gate electrodes GE may be disposed repeatedly in the first direction D1. The plurality of gate electrodes GE may surround the stacked lower and upper channel patterns LCH and UCH.

The plurality of gate electrodes GE may extend in the third direction D3 from an upper surface of the substrate 100 to a lower surface of a gate capping pattern GP, which will be described later. The plurality of gate electrodes GE may extend in the third direction D3 from the lower channel pattern LCH of the lower active region LAR to the upper channel pattern UCH of the upper active region UAR.

The gate electrode GE may be provided on an upper surface, a bottom surface, and both sidewalls of each of the first to fourth semiconductor patterns SP1 to SP4. For example, the transistor according to the present embodiment may include a three-dimensional field effect transistor (e.g., MBCFET (multi-bridge-channel MOSFET) or GAAFET (gate-all-around field effect transistor)) in which the gate electrode GE three-dimensionally surrounds the channel.

A plurality of gate electrodes GE may be provided. The gate electrodes GE may be spaced apart from each other in the first direction D1 and the second direction D2. For example, in one single height cell SHC, the gate electrodes GE may be spaced apart from each other in the second direction D2.

The gate electrode GE may include a lower gate electrode LGE provided as a part of the lower tier of the FEOL layer, and an upper gate electrode UGE provided as a part of the upper tier of the FEOL layer. The lower gate electrode LGE and the upper gate electrode UGE may vertically overlap each other. In one embodiment of the inventive concept, the lower gate electrode LGE and the upper gate electrode UGE may be connected to each other. For example, the lower gate electrode LGE may be integrally formed with the upper gate electrode UGE, and the gate electrode GE according to the present embodiment may be a common gate electrode in which the lower gate electrode LGE on the lower channel pattern LCH and the upper gate electrode UGE on the upper channel pattern UCH are connected to each other.

The lower gate electrode LGE may include a first inner electrode PO1 interposed between the first lower insulating layer LIL1 and the first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or the seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be disposed on both sidewalls of the gate electrode GE. The pair of gate spacers GS may be disposed on both sidewalls of the outer electrode PO6, respectively. The gate spacers GS may extend in the first direction D1 along the gate electrode GE. As an example, the gate spacers GS may include at least one of SiCN (silicon carbon nitride), SiCON (silicon carbon oxynitride), and SiN (silicon nitride). As another example, the gate spacers GS may include a multi-layer made of at least two of SiCN, SiCON, and SiN.

A gate capping pattern GP may be provided on an upper surface of the gate electrode GE. The gate capping pattern GP may extend in the first direction D1 along the gate electrode GE. As an example, the gate capping pattern GP may include at least one of SiON (silicon oxynitride), SiCN, SiCON, and SiN.

A gate insulating layer GI may be interposed between the gate electrode GE and the first to fourth semiconductor patterns SP1 to SP4. The gate insulating layer GI may include a silicon oxide layer, a silicon oxynitride layer, and/or a high-k dielectric layer. As an example, the gate insulating layer GI may include a silicon oxide layer directly covering the surface of the semiconductor patterns SP1 to SP4 and a high-k dielectric layer on the silicon oxide layer. For example, the gate insulating layer GI may include a multi-layer of a silicon oxide layer and a high-k dielectric layer. The high-k dielectric layer may include a high dielectric constant material that has a higher dielectric constant than that of the silicon oxide layer.

A second interlayer insulating layer 120 and a third interlayer insulating layer 130 may be sequentially provided on the lower source drain pattern LSD and the first interlayer insulating layer 110. The second interlayer insulating layer 120 may cover the upper source drain pattern USD. The third interlayer insulating layer 130 may cover the second interlayer insulating layer 120.

Upper active contacts UAC may be provided through the second and third interlayer insulating layers 120 and 130 and electrically connected to the upper source drain patterns USD, respectively. For example, an upper surface of the upper active contact UAC may be coplanar with an upper surface of the third interlayer insulating layer 130. Terms such as “same,” “symmetrical” “equal,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

An upper gate contact UGC may be provided that penetrates the third interlayer insulating layer 130 and the gate capping pattern GP and is electrically connected to the upper gate electrode UGE. The upper gate contact UGC may include conductive materials such as a metal of the upper active contact UAC and the upper gate contact UGC.

A separation trench STR may separate gate electrodes GE adjacent to each other in the first direction D1 in a gate group. Accordingly, the adjacent gate electrodes GE may be spaced apart in the first direction D1 by the separation trench STR. The separation trench STR may extend in the second direction D2 and the third direction D3. A width of the separation trench STR in the first direction D1 may become smaller as it goes downward.

A separation insulating pattern SI may fill an interior of the separation trench STR. The separation insulating pattern SI may extend in each of the second direction D2 and the third direction D3 in the separation trench STR. The separation insulating pattern SI may be interposed between a pair of gate electrodes GE adjacent to each other in the first direction D1. The separation insulating pattern SI may include an insulating material such as silicon oxide and silicon nitride.

A fourth interlayer insulating layer 140 may be provided on the third interlayer insulating layer 130. A first metal layer M1 may be provided in the fourth interlayer insulating layer 140. The first metal layer M1 may include upper interconnections UMI. The first metal layer M1 may further include an upper via UVI. The upper via UVI may electrically connect an upper interconnection UMI to the upper active contact UAC or the upper gate contact UGC. Each of the upper interconnection UMI and the upper via UVI may include a conductive material such as metal.

Additional metal layers (e.g., M2, M3, M4, etc.) may be stacked on the first metal layer M1. The first metal layer M1 and the metal layers (e.g., M2, M3, M4, etc.) on the first metal layer M1 may form a back-end-of-line (BEOL) layer of the semiconductor device. The metal layers (e.g., M2, M3, M4, etc.) on the first metal layer M1 may include routing interconnections for connecting logic cells to each other.

A lower interlayer insulating layer 210 may be provided under a lower surface of the substrate 100. A lower gate contact LGC electrically connected to the lower gate electrode LGE may be provided between the lower interlayer insulating layer 210 and the lower gate electrode LGE. A backside metal layer BSM may be provided in the lower interlayer insulating layer 210. The backside metal layer BSM may include a lower contact LC, lower interconnections LMI, and a lower via LVI. The lower contact LC may be electrically connected to the lower source drain pattern LSD through the lower active contact LAC. The lower via LVI may electrically connect the lower interconnection LMI to the lower active contact LAC, the lower contact LC, or the lower gate contact LGC. Each of the lower gate contact LGC, the lower contact LC, the lower interconnection LMI, and the lower via LVI may include a conductive material such as metal.

Additional underlying metal layers may be stacked below the backside metal layer BSM. In one embodiment of the invention, the underlying metal layers may include a power transmission network. The power transmission network may include a wiring network for applying a source voltage (VSS) and a drain voltage (VDD) to the backside metal layer BSM.

The separation trench STR may include first separation trenches STR1 and second separation trenches STR2 arranged alternately in the first direction D1. As an example, a single height cell SHC may be interposed between the first separation trench STR1 and the second separation trench STR2. The single height cells SHC may include a first single height cell SHC1, a second single height cell SHC2, and a third single height cell SHC3 arranged to be spaced apart from each other in the first direction D1. The first separation trench STR1 may be interposed between the first and second single height cells SHC1 and SHC2, and the second separation trench STR2 may be interposed between the second and third single height cells SHC2 and SHC3.

The separation insulating pattern SI may include a first separation insulating pattern SI1 filling the inside of the first separation trench STR1 and a second separation insulating pattern SI2 filling the inside of the second separation trench STR2.

The first separation insulating pattern SI1 may have a first width W1 in the first direction D1 in a plan view, and the second separation insulating pattern SI2 may have a second width W2 in the first direction D1 in a plan view. A plurality of conductive plates CP, which will be described later, may be provided in the first separation insulating pattern SI1, and the plurality of conductive plates CP may not be provided in the second separation insulating pattern SI2. The second separation insulating pattern SI2 may not require space for the plurality of conductive plates CP to be disposed therein, and accordingly, the second width W2 of the second separation insulating pattern SI2 may be smaller than the first width W1 of the first separation insulating pattern SI1. As a result, the second height CHT2 of the single height cell SHC may become relatively small, and thus the area of the single height cell SHC may become relatively small. Therefore, integration of the three-dimensional semiconductor device may be improved.

The first separation insulating pattern SI1 may include liner insulating layers LN that conformally cover both side walls of the first separation trench STR1 and a first filling pattern FL1 between the liner insulating layers LN. The liner insulating layer LN and the first filling pattern FL1 may be spaced apart from each other in the first direction D1. One liner insulating layer LN may be interposed between a first conductive plate CP1 and a first gate electrode GE1, which will be described later, and another liner insulating layer may be between a second conductive plate CP2 and a second gate electrode GE2, which will be described later. The first filling pattern FL1 may be interposed between the first and second conductive plates CP1 and CP2, which will be described later. Along the third direction D3, a width of each of the liner insulating layers LN in the first direction D1 may be substantially the same. A width of the first filling pattern FL1 in the first direction D1 may become smaller as it goes downward.

A plurality of conductive plate CP may be provided in the first separation insulating pattern SI1. The plurality of conductive plates CP may be interposed between gate electrodes GE adjacent to each other in the first direction D1. The first single height cell SHC1 may include first gate electrodes GE1 arranged to be spaced apart from each other in the second direction D2, and the second single height cell SHC2 may include the second gate electrodes GE2 arranged to be spaced apart from each other in the second direction D2. The plurality of conductive plates CP may extend in each of the second direction D2 and the third direction D3 in the first separation insulating pattern SI1. Specifically, the plurality of conductive plates CP may extend from an upper surface to a lower surface of the first separation insulating pattern SI1. The plurality of conductive plates CP may include a conductive material such as metal.

A plurality of conductive plates CP may be provided. The conductive plates CP may be arranged adjacent to each other in the first direction D1 and the second direction D2. A conductive separation region CS may be defined between the conductive plates CP adjacent to each other in the second direction D2. The conductive plates CP may be spaced apart from each other in the second direction D2 by the conductive separation region CS. The first separation insulating pattern SI1 may further include a second filling pattern FL2 in the conductive isolation region CS. The second filling pattern FL2 may include an insulating material, and thus the conductive plates CP spaced apart from each other in the second direction D2 may be electrically insulated. For example, in a portion of the first separation insulating pattern SI1, the liner insulating layer LN, the first filling pattern FL1, and the second filling pattern FL2 may form an integrated shape without an interface therebetween.

The plurality of conductive plates CP may include a first conductive plate CP1 and a second conductive plate CP2 adjacent to each other in the first direction D1 in the first separation insulating pattern SI1. The first conductive plate CP1 may be closer to the first gate electrode GE1 than the second gate electrode GE2, and the second conductive plate CP2 may be closer to the second gate electrode GE2 than the first gate electrode GE1. The first conductive plate CP1 and the second conductive plate CP2 may be spaced apart from each other with the first filling pattern FL1 interposed therebetween. As an example, each of the first and second conductive plates CP1 and CP2 may have a shape of a plate extending in each of the second direction D2 and the third direction D3. When viewed in a plan view, the liner insulating layer LN, the first conductive plate CP1, the first filling pattern FL1, and the second conductive plate CP2 may be sequentially arranged in the first direction D1, in the first separation trench STR1.

Each of the first and second conductive plates CP1 and CP2 may be provided in plural numbers. The first conductive plates CP1 may be spaced apart from each other in the second direction D2 and electrically insulated by the above-described conductive separation region CS. The second conductive plates CP2 may be spaced apart from each other in the second direction D2 and electrically insulated by the above-described conductive separation region CS.

Each of the first and second conductive plates CP1 and CP2 may conformally cover a sidewall of each of the liner insulating layers LN. For example, along the third direction D3, a width of the first conductive plate CP1 in the first direction D1 may be substantially the same. Likewise, along the third direction D3, a width of the second conductive plate CP2 in the first direction D1 may be substantially the same. For example, widths of the first and second conductive plates CP1 and CP2 in the first direction D1 may be substantially the same along the third direction.

The liner insulating layer LN may conformally cover a sidewall of the first separation trench STR1. Accordingly, in the third direction D3, a distance between the first conductive plate CP1 and the first gate electrode GE1 may be substantially the same. Likewise, in the third direction D3, a distance between the second conductive plate CP2 and the second gate electrode GE2 may be substantially the same. The distance between the first conductive plate CP1 and the first gate electrode GE1 in the first direction is substantially the same along the third direction, The distance between the second conductive plate CP2 and the second gate electrode GE2 in the first direction is substantially the same along the third direction. For example, at substantially the same level, a distance between the first conductive plate CP1 and the first gate electrode GE1 may be substantially the same as a distance between the second conductive plate CP2 and the second gate electrode GE2. As used herein, “a level” refers to a height level with respect to the third direction D3.

Both sides of the first conductive plate CP1 may have profiles inclined in substantially the same direction. Both sides of the second conductive plate CP2 may have profiles inclined in substantially the same direction.

When viewed in a cross-sectional view, the first conductive plate CP1 and the second conductive plate CP2 may have profiles that are symmetrical to each other. Specifically, when viewed in a cross-sectional view, the first conductive plate CP1 and the second conductive plate CP2 may have mirror symmetry with respect to the first filling pattern FL1.

A first distance DS1 is a distance between the first conductive plate CP1 and the second conductive plate CP2. A first distance DS1 at substantially the same level as an upper surface of the first separation insulating pattern SI1 may be greater than a second distance DS2 at substantially the same level as a lower surface of the first separation insulating pattern SI1. For example, a first distance DS1 at the level of an upper surface of the first separation insulating pattern SI1 may be greater than a second distance DS2 at the level of a lower surface of the first separation insulating pattern SI1. A distance between the first conductive plate CP1 and the second conductive plate CP2 may decrease as it goes downward (or decreases with respect to a downward direction).

Hereinafter, neighboring components electrically connected to each of the first and second conductive plates CP1 and CP2 will be described in detail with reference to FIGS. 4 and 5A to 5E, although the scope of the invention is not limited thereto. Many modifications and changes of the arrangement of each of the first and second conductive plates CP1 and CP2 and the neighboring components may be possible.

Referring to FIGS. 4 and 5A to 5E, the lower source drain pattern LSD may include a first lower source drain pattern LSD1 and a second lower source drain pattern LSD2 spaced apart from each other in the second direction D2 in the single height cells SHC1 and SHC2. The upper source drain pattern USD may include a first upper source drain pattern USD1 on the first lower source drain pattern LSD1 and a second upper source drain pattern USD2 on the second lower source drain pattern LSD2.

The first and second lower source drain patterns LSD1 and LSD2 of the first single height cell SHC1 may be adjacent to the first and second lower source drain patterns LSD1 and LSD2 of the second single height cell SHC2 in the first direction D1, respectively. The first and second upper source drain patterns USD1 and USD2 of the second single height cell SHC2 may be adjacent to the first and second upper source drain patterns USD1 and USD2 of the second single height cell SHC2 in the first direction D1, respectively.

The lower active contact LAC may include a first lower active contact LAC1 below the first lower source drain pattern LSD1 and a second lower active contact LAC2 below the second lower source drain pattern LSD2. The upper active contact UAC may include a first upper active contact UAC1 on the first upper source drain pattern USD1 and a second upper active contact UAC2 on the second upper source drain pattern USD2.

The first conductive plate CP1 may be electrically connected to one of the first and second lower source drain patterns LSD1 and LSD2 in the first single height cell SHC1 and the first and second upper source drain patterns USD1 and USD2 in the first single height cell SHC1.

As an example, the first conductive plate CP1 may be electrically connected to the first upper source drain pattern USD1 of the first single height cell SHC1. In this case, a first upper contact UCa may be provided on an upper surface of the first upper active contact UAC1. The first upper contact UCa may cover the upper surface of the first upper active contact UAC1 and may extend to cover an upper surface of the first conductive plate CP1. Accordingly, the first conductive plate CP1 and the first upper source drain pattern USD1 may be electrically connected to each other through the first upper contact UCa and the first upper active contact UAC1. The first upper contact UCa may be spaced apart from the second conductive plate CP2 and may be electrically insulated.

As another example, although not shown in the drawing, the first upper contact UCa may not be provided, and the first upper active contact UAC1 may be in direct contact with the first conductive plate CP1 and be electrically connected to each other.

The second conductive plate CP2 may be electrically connected to one of the first and second lower source drain patterns LSD1 and LSD2 in the second single height cell SHC2 and the first and second upper source drain patterns USD1 and USD2 in the second single height cell SHC2.

As an example, the second conductive plate CP2 may be electrically connected to the first lower source drain pattern LSD1 of the second single height cell SHC2. In this case, the lower contact LC may include a first lower contact LCa that covers a lower surface of the first lower active contact LAC1 and extends to cover a lower surface of the second conductive plate CP2. Accordingly, the second conductive plate CP2 and the first lower source drain pattern LSD1 may be electrically connected to each other through the first lower contact LCa and the first lower active contact LAC1. The first lower contact LCa may be spaced apart from the first conductive plate CP1 and may not be electrically connected to the first conductive plate CP1.

The first conductive plate CP1 may be electrically connected to either the backside metal layer BSM or the first metal layer M1. For example, the first conductive plate CP1 is electrically connected to the first upper source drain pattern USD1, the first conductive plate CP1 may be electrically connected to the backside metal layer BSM. Specifically, the lower contact LC may include a second lower contact LCb in contact with a lower surface of the first conductive plate CP1. The lower via LVI may be interposed between the lower interconnection LMI and the second lower contact LCb. Accordingly, the first conductive plate CP1 and the lower interconnection LMI may be electrically connected to each other through the second lower contact LCb and the lower via LVI. In summary, the lower interconnection LMI and the first upper source drain pattern USD1 may be electrically connected to each other through the first conductive plate CP1.

The second lower contact LCb may be spaced apart from the first lower contact LCa and may not be electrically connected to the first lower contact LCa. For example, the second lower contact LCb may be adjacent to the first lower contact LCa in the first direction D1, but the invention is not limited thereto.

The second conductive plate CP2 may be electrically connected to either the backside metal layer BSM or the first metal layer M1. For example, the second conductive plate CP2 is electrically connected to the first lower source drain pattern LSD1, the second conductive plate CP2 may be electrically connected to the first metal layer M1. Specifically, a second upper contact UCb may be provided on an upper surface of the second conductive plate CP2. The upper via UVI may be interposed between the upper interconnection UMI and the second upper contact UCb. Accordingly, the second conductive plate CP2 and the upper interconnection UMI may be electrically connected to each other through the second upper contact UCb and the upper via UVI. In summary, the upper interconnection UMI and the first lower source drain pattern LSD1 may be electrically connected to each other through the second conductive plate CP2.

The second upper contact UCb may be spaced apart from the first upper contact UCa and may not be electrically connected to the first upper contact UCa. For example, the second upper contact UCb may be adjacent to the first upper contact UCa in the first direction D1, but the invention is not limited thereto.

According to embodiments of the invention, a component of a logic element (e.g., the first single height cell SHC1) and a corresponding component of a second logic element (e.g., the second single height cell SHC2) may be arranged to have a symmetric layout of a cell array in a plan view. For example, in embodiments of the invention, a component electrically connected to the bottom tier of the FEOL layer and a corresponding component electrically connected to the top tier of the FEOL layer may be arranged symmetrically with respect to a horizontal axis crossing the first filling pattern FL1 and parallel to the second direction in a plan view. In embodiments of the invention, a component electrically connected to the first conductive plate CP1 and a corresponding component electrically connected to the second conductive plate CP2 may be arranged symmetrically with respect to a horizontal axis crossing the first filling pattern FL1 and parallel to the second direction in a plan view. For example, as shown in the plan view of FIG. 4, the lower via LVI and the upper via UVI may be arranged symmetrically with respect to a horizontal axis crossing the first filling pattern FL1 and parallel to the second direction D2. Also, as shown in the plan view of FIG. 4, first upper contact Uca and the first lower contact LCa may be arranged symmetrically with respect to a horizontal axis crossing the first filling pattern FL1 and parallel to the second direction. In an embodiment, though not shown in the drawings, other components the BEOL layer and corresponding component of the backside metal layer BSM also may be arranged symmetrically with respect to a horizontal axis crossing the first filling pattern FL1 and parallel to the second direction in a plan view. The symmetry described above may be accomplished by utilizing the symmetrical arrangement of the first and second conductive plates CP1 and CP2 formed in the first separation insulating pattern SI1.

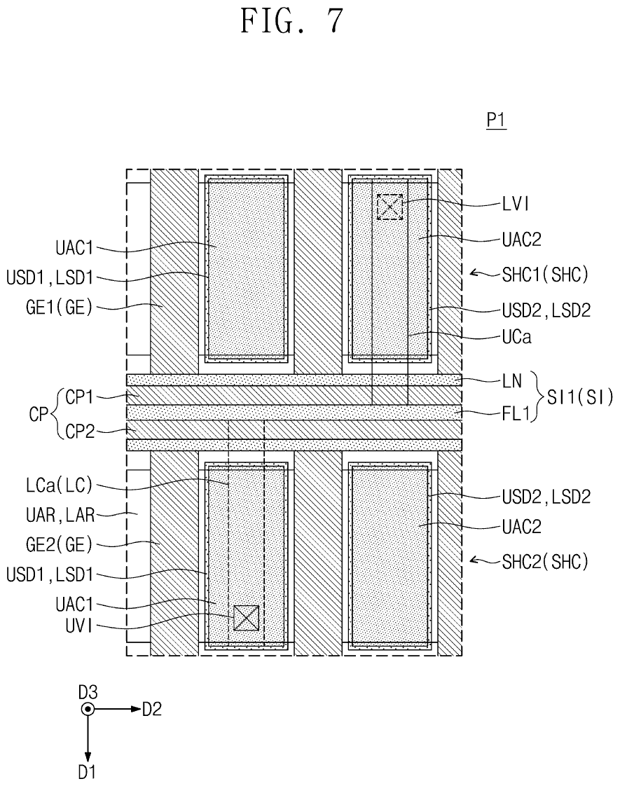

Hereafter, with reference to FIGS. 7, 8A to 8D, 9, and 10A to 10D, other embodiments of the inventive concept will be described. To simplify the explanation, descriptions of content that overlaps with the above-mentioned content are omitted.

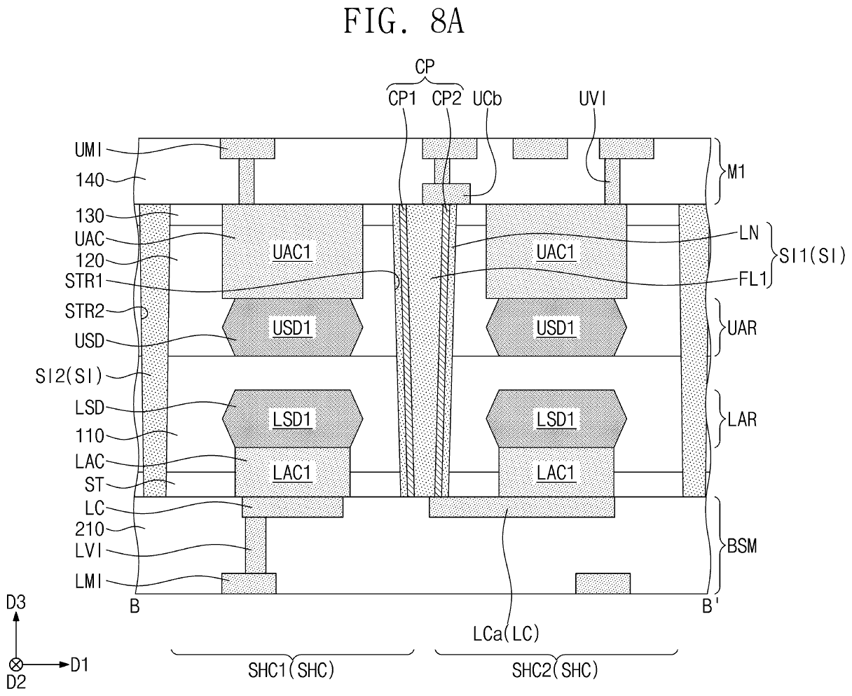

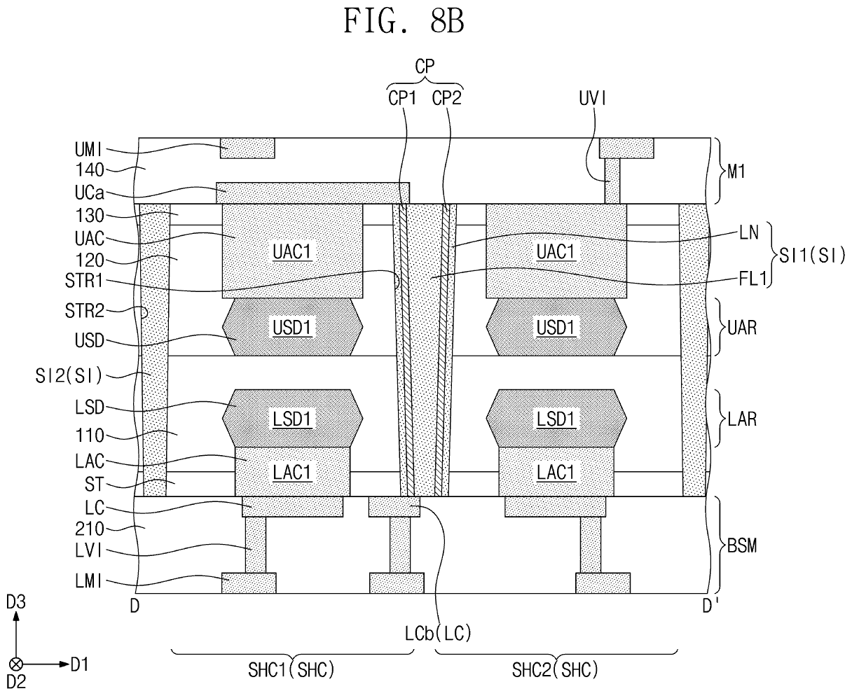

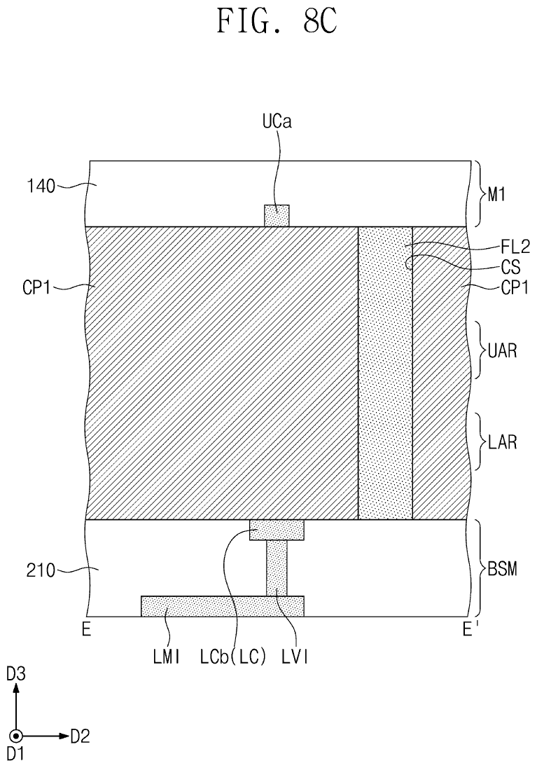

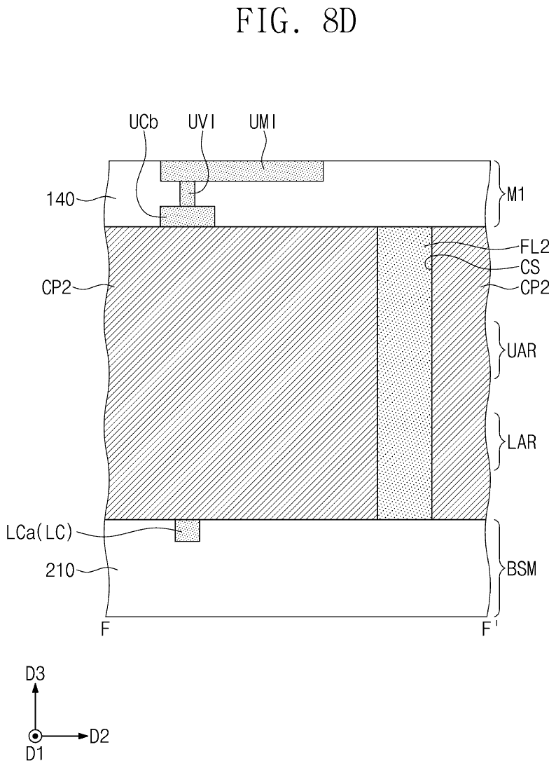

FIG. 7 is an enlarged view corresponding to portion ‘P1’ in FIG. 3. FIGS. 8A to 8D are cross-sectional views taken along lines B-B′, D-D′, E-E′, and F-F′ of FIG. 3, respectively.

With reference to FIGS. 7 and 8A to 8D, various arrangement manners of neighboring components electrically connected to each of the first and second conductive plates CP1 and CP2 will be described in detail.

Referring to FIGS. 7 and 8A to 8D, as an example, the first conductive plate CP1 may be electrically connected to the second upper source drain pattern USD1 of the first single height cell SHC1. In this case, the first upper contact UCa may be provided on the upper surface of the second upper active contact UAC2. The first upper contact UCa may extend to cover the upper surface of the second upper active contact UAC2 and the upper surface of the first conductive plate CP1. Accordingly, the first conductive plate CP1 and the second upper source drain pattern USD2 may be electrically connected to each other through the first upper contact UCa and the second upper active contact UAC2. Accordingly, the backside metal layer BSM and the second upper source drain pattern USD2 may be electrically connected through the first conductive plate CP1.

The arrangement of neighboring components electrically connected to the second conductive plate CP2 may be the same/similar to that described with reference to FIGS. 3, 4, 5A to 5E.

The arrangement of the neighboring components electrically connected to each of the first and second conductive plates CP1 and CP2 is not limited to that described with reference to FIGS. 3, 7 and 8A to 8D, and many modifications and changes may be possible.

For example, the first conductive plate CP1 is electrically connected to the first metal layer M1 and the second upper contact UCb, and the first conductive plate CP1 may be electrically connected to one of the lower source drain pattern LSD adjacent to the first conductive plate CP1 in the first direction D1 through the first lower contact LCa in the first single height cell SHC1. In this case, one of the first metal layer M1 and the lower source drain patterns LSD may be electrically connected through the first conductive plate CP1.

As an example, the first conductive plate CP1 is electrically connected to the backside metal layer BSM and the second lower contact LCb, and the first conductive plate CP1 may be electrically connected to one of the upper source drain patterns LSD adjacent to the first conductive plate CP1 in the first direction D1 through the first upper contact Uca, in the first single height cell SHC1. In this case, one of the backside metal layer BSM and the upper source drain patterns USD may be electrically connected through the first conductive plate CP1.

For example, the second conductive plate CP2 is electrically connected to the first metal layer M1 and the second upper contact UCb, and the second conductive plate CP2 may be electrically connected to one of the lower source drain patterns LSD adjacent to the second conductive plate CP2 in the first direction D1 through the first lower contact LCa, in the second single height cell SHC2. In this case, one of the first metal layer M1 and the lower source drain patterns LSD may be electrically connected through the second conductive plate CP2.

As an example, the second conductive plate CP2 is electrically connected to the backside metal layer BSM and the second lower contact LCb, and the second conductive plate CP2 may be electrically connected to one of the upper source drain patterns LSD adjacent to the second conductive plate CP2 in the first direction D1 through the first upper contact UCa, in the second single height cell SHC2. In this case, one of the backside metal layer BSM and the upper source drain patterns USD may be electrically connected through the second conductive plate CP2.

According to the inventive concept, the first and second conductive plates CP1 and CP2 adjacent to each other in the first direction D1 may be provided in one first separation trench STR1. Accordingly, the source drain patterns LSD and USD of two single height cells SHC1 and SHC2 may be electrically connected to the neighboring components (e.g., backside metal layer BSM and first metal layer M1) through two conductive plates CP1 and CP2 provided in one separation trench STR1. As a result, design freedom of the three-dimensional semiconductor device may be improved compared to providing one conductive plate in one separation trench.

According to embodiments of the invention, a component of a logic element (e.g., the first single height cell SHC1) and a corresponding component of a second logic element (e.g., the second single height cell SHC2) may be arranged to have a symmetric layout of a cell array in a plan view. For example, in embodiments of the invention, a component electrically connected to the bottom tier of the FEOL layer and a corresponding component electrically connected to the top tier of the FEOL layer may be arranged symmetrically with respect to a symmetry point in the first filling pattern FL1 in a plan view. In embodiments of the invention, a component electrically connected to the first conductive plate CP1 and a corresponding component electrically connected to the second conductive plate CP2 may be arranged symmetrically with respect to a symmetry point in the first filling pattern FL1 in a plan view. For example, as shown in the plan view of FIG. 7, the lower via LVI and the upper via UVI may be arranged symmetrically with respect to a symmetry point in the first filling pattern FL1. Also, as shown in the plan view of FIG. 4, first upper contact Uca and the first lower contact LCa may be arranged symmetrically with respect to a symmetry point in the first filling pattern FL1. In an embodiment, though not shown in the drawings, other components the BEOL layer and corresponding component of the backside metal layer BSM also may be arranged symmetrically with respect to a symmetry point in the first filling pattern FL1 in a plan view. The symmetry described above may be accomplished by utilizing the symmetrical arrangement of the first and second conductive plates CP1 and CP2 formed in the first separation insulating pattern SI1.

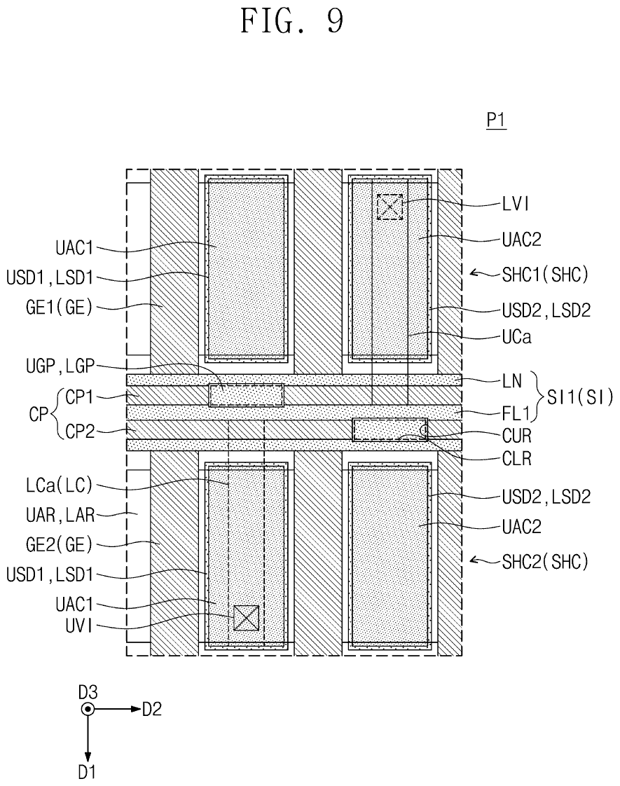

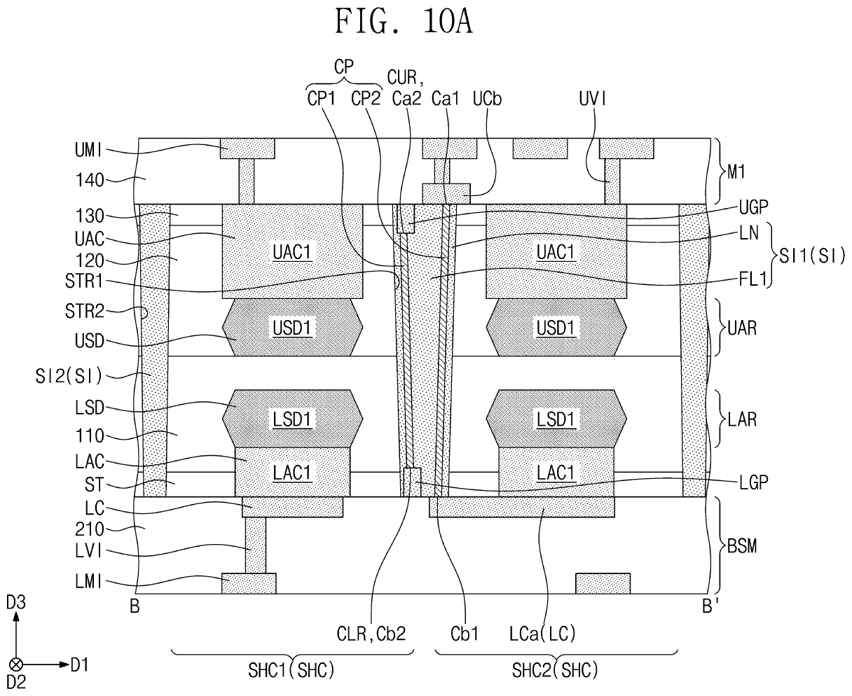

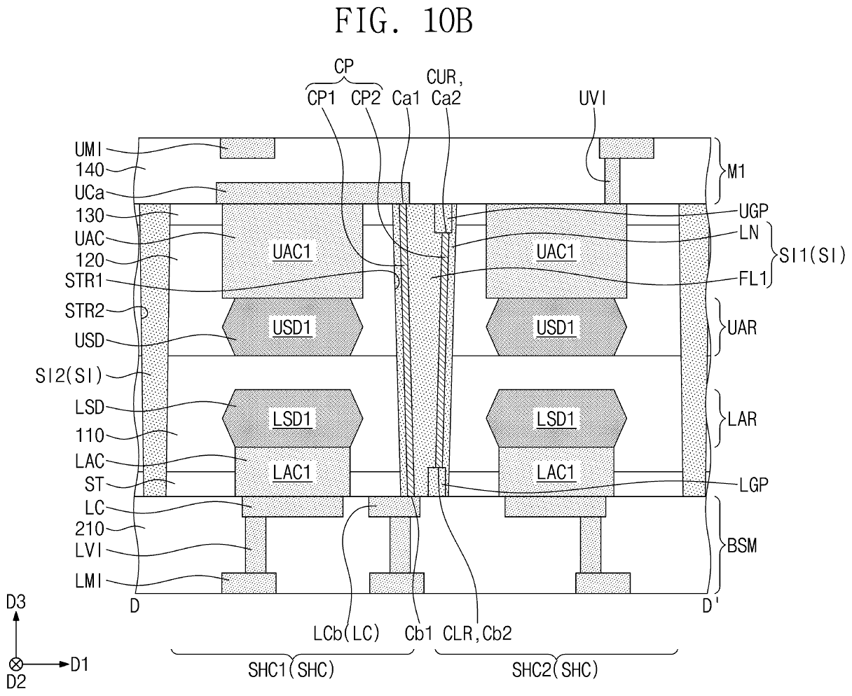

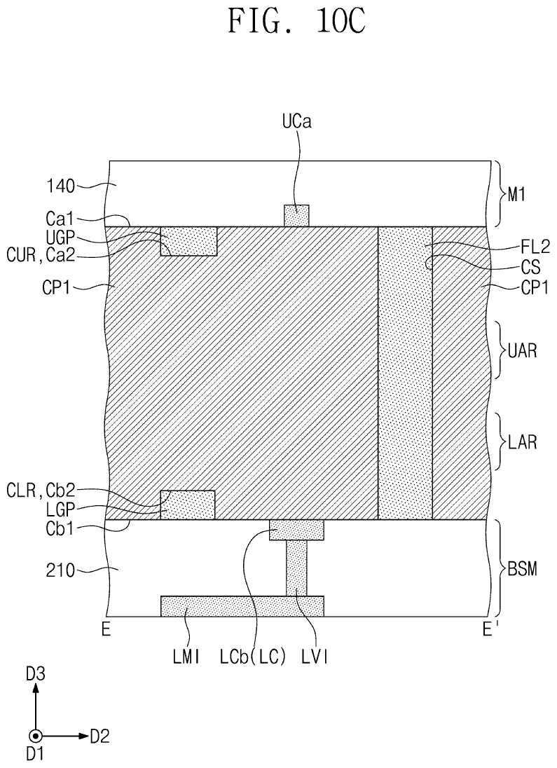

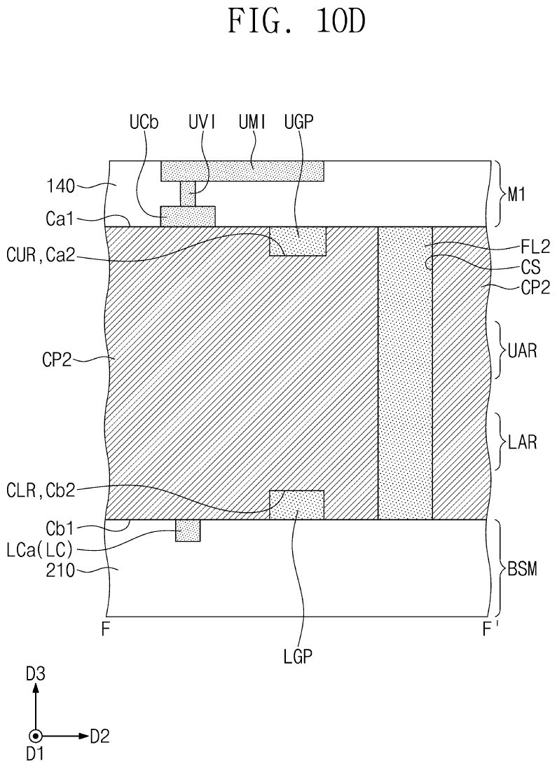

FIG. 9 is an enlarged view corresponding to portion ‘P1’ in FIG. 3. FIGS. 10A to 10D are cross-sectional views taken along lines B-B′, D-D′, E-E′, and F-F′ of FIG. 3, respectively.

Referring to FIGS. 9 and 10A to 10D, each of the first and second conductive plates CP1 and CP2 described with reference to FIGS. 7 and 8A to 8D may include an upper recess region CUR and a lower recess region CLR. An upper gap fill pattern UGP may fill the upper recess region CUR, and a lower gap fill pattern LGP may fill the lower recess region CLR. The upper gap fill pattern UGP and lower gap fill pattern LGP may include an insulating material. As an example, the upper gap fill pattern UGP and the lower gap fill pattern LGP may include the same material as the first separation insulating pattern SI1. In this case, the upper gap fill pattern UGP and the lower gap fill pattern LGP may form an integrated shape with the first separation insulating pattern SI1 without an interface.

Each of the first and second conductive plates CP1 and CP2 may have upper surfaces at different levels due to the upper recess region CUR. Each of the first and second conductive plates CP1 and CP2 may include a first upper surface Ca1 in contact with the fourth interlayer insulating layer 140 and a second upper surface Ca2 on an inner lower surface of the upper recess region CUR. The first upper surface Ca1 may be positioned at a higher level than the second upper surface Ca2.

Each of the first and second conductive plates CP1 and CP2 may have lower surfaces at different levels due to the lower recess region LUR. Each of the first and second conductive plates CP1 and CP2 may include a first lower surface Cb1 in contact with the lower interlayer insulating layer 210 and a second lower surface Cb2 recessed by the lower recess region LUR. The first lower surface Cb1 may be positioned at a lower level than the second lower surface Cb2.

When viewed in a plan view, the upper recess region CUR may be adjacent to the first upper contact UCa in the first direction D1. For example, the first conductive plate CP1 and the first upper contact UCa may be electrically connected, and when viewed in a plan view, the upper recess region CUR in the second conductive plate CP2 may be adjacent to the first upper contact Uca in the first direction D1. In this case, due to misalignment of the first upper contact UCa, even though the first upper contact UCa extends onto the upper surface of the second conductive plate CP2, the first upper contact UCa and the second conductive plate CP2 may be spaced apart from each other by the upper recess region CUR. In addition, the first upper contact UCa and the second conductive plate CP2 may be electrically insulated by the upper gap fill pattern UGP that fills the upper recess region CUR.

When viewed in a plan view, the upper recess region CUR may be adjacent to the second upper contact UCb in the first direction D1. For example, the second conductive plate CP2 and the second upper contact UCb may be electrically connected, and when viewed in a plan view, the upper recess region CUR in the first conductive plate CP1 may be adjacent to the second upper contact UCb in the first direction D1. In this case, due to misalignment of the second upper contact UCb, even though the second upper contact UCb extends onto the upper surface of the first conductive plate CP1, the second upper contact UCb and the first conductive plate CP1 may be spaced apart from each other by the upper recess region CUR. In addition, the second upper contact UCb and the first conductive plate CP1 may be electrically insulated by the upper gap fill pattern UGP that fills the upper recess region CUR.

When viewed in a plan view, the lower recess region CLR may be adjacent to the first lower contact LCa in the first direction D1. For example, the second conductive plate CP2 and the first lower contact LCa may be electrically connected, and when viewed in a plan view, the lower recess region CLR in the first conductive plate CP1 may be adjacent to the first lower contact LCa in the first direction D1. In this case, due to misalignment of the first lower contact LCa, even though the first lower contact LCa extends onto the lower surface of the first conductive plate CP1, the first lower contact LCa and the first conductive plate CP1 may be spaced apart from each other by the lower recess region CLR. In addition, the first lower contact LCa and the first conductive plate CP1 may be electrically insulated by the lower gap fill pattern LGP that fills the lower recess region CLR.

When viewed in a plan view, the lower recess region CLR may be adjacent to the second lower contact LCb in the first direction D1. For example, the first conductive plate CP1 and the second lower contact LCb may be electrically connected, and when viewed in a plan view, the lower recess region CLR in the second conductive plate CP2 may be adjacent to the second lower contact LCb in the first direction D1. In this case, due to misalignment of the second lower contact LCb, even though the second lower contact LCb extends onto the lower surface of the second conductive plate CP2, the second lower contact LCb and the second conductive plate CP2 may be spaced apart from each other by the lower recess region CLR. In addition, the second lower contact LCb and the second conductive plate CP2 may be electrically insulated by the lower gap fill pattern LGP that fills the lower recess region CLR.

According to the inventive concept, each of the first and second conductive plates CP1 and CP2 may include the upper recess region CUR and the lower recess region CLR. Accordingly, unnecessary electrical connections between each of the first and second conductive plates CP1 and CP2 and neighboring components may be prevented. As a result, process defects in three-dimensional semiconductor devices may be prevented and productivity of three-dimensional semiconductor devices may be improved.

The arrangement of each of the upper recess region CUR and lower recess region CLR and the neighboring components has been described with reference to FIGS. 9 and 10A to 10D, but the invention is not limited thereto, and many modifications and changes may be possible.

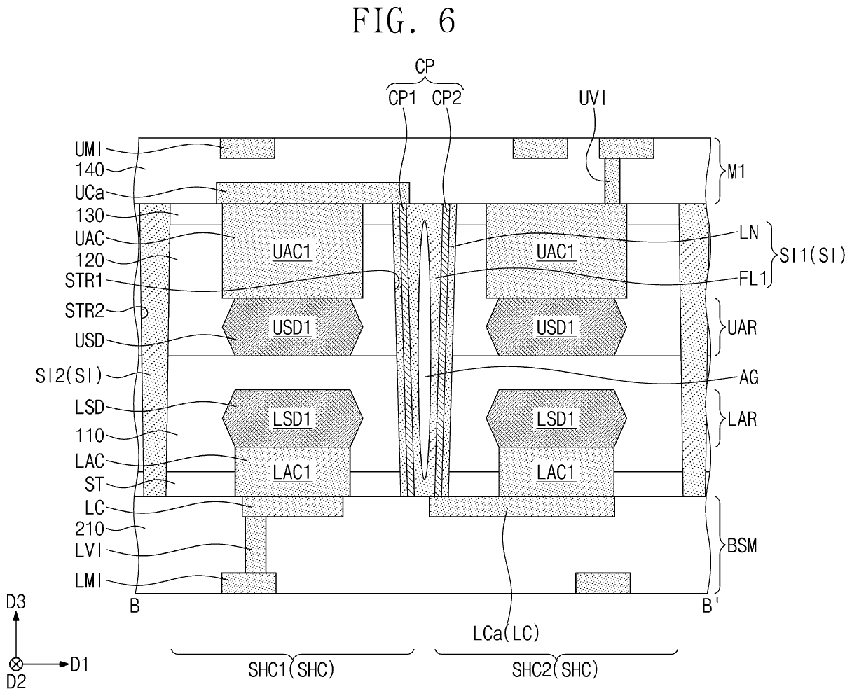

FIG. 6 is a cross-sectional view taken along line B-B′ in FIG. 3.

Referring to FIGS. 3 and 6, a first filling pattern FL1 of the first separation insulating pattern SI1 may include an air gap AG therein. Accordingly, the air gap AG may be interposed between the first conductive plate CP1 and the second conductive plate CP2. As a result, electrical interference between the first conductive plate CP1 and the second conductive plate CP2 may be reduced, and the electrical characteristics of the three-dimensional semiconductor device may be improved. It should be appreciated that an “air gap” may comprise a gap having air or other gases (e.g., such as those present during manufacturing) or may comprise a gap forming a vacuum therein.

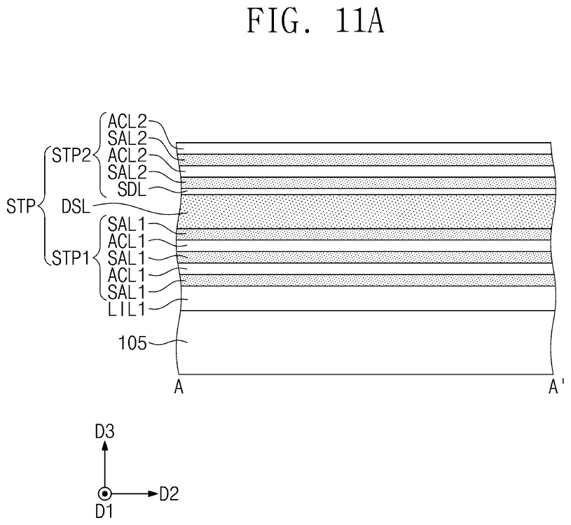

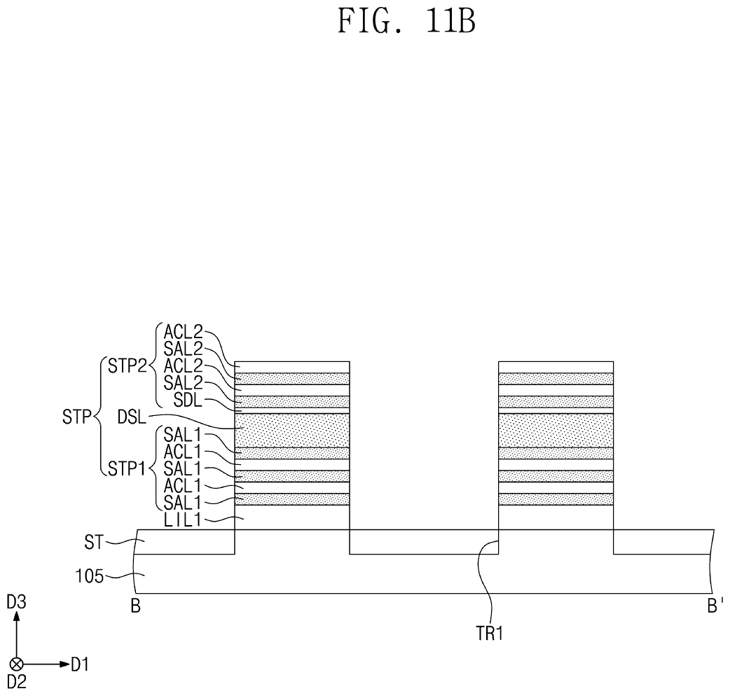

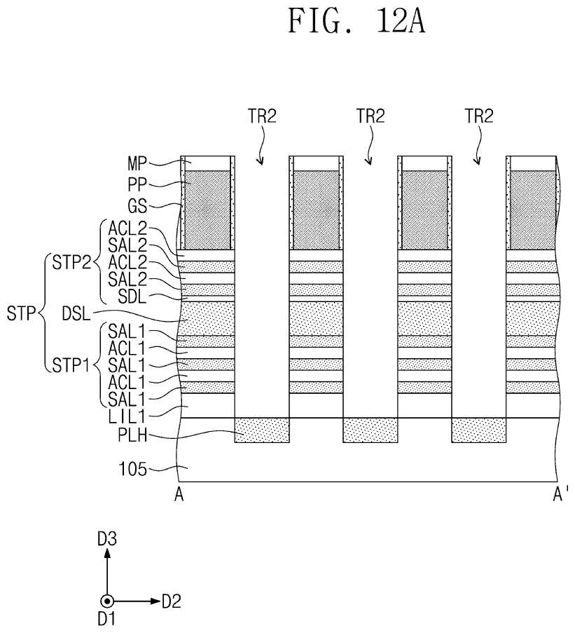

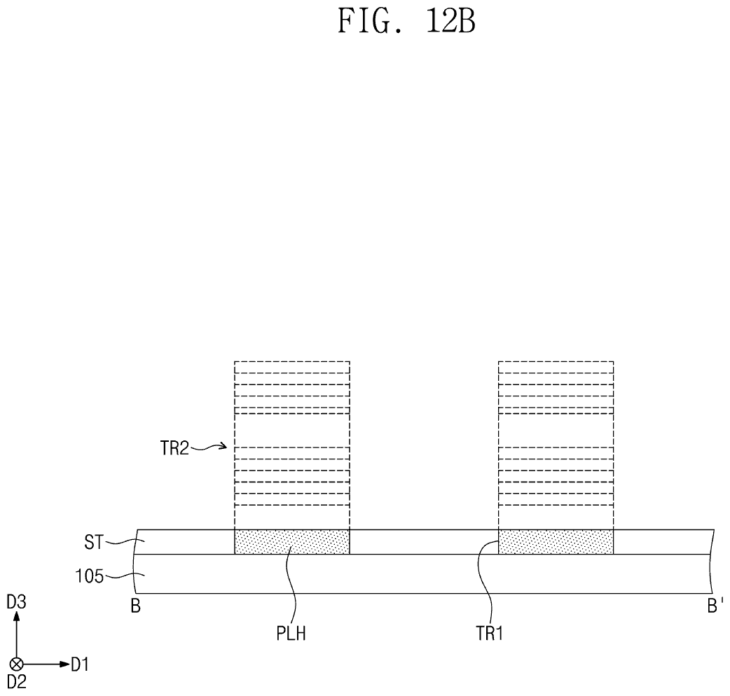

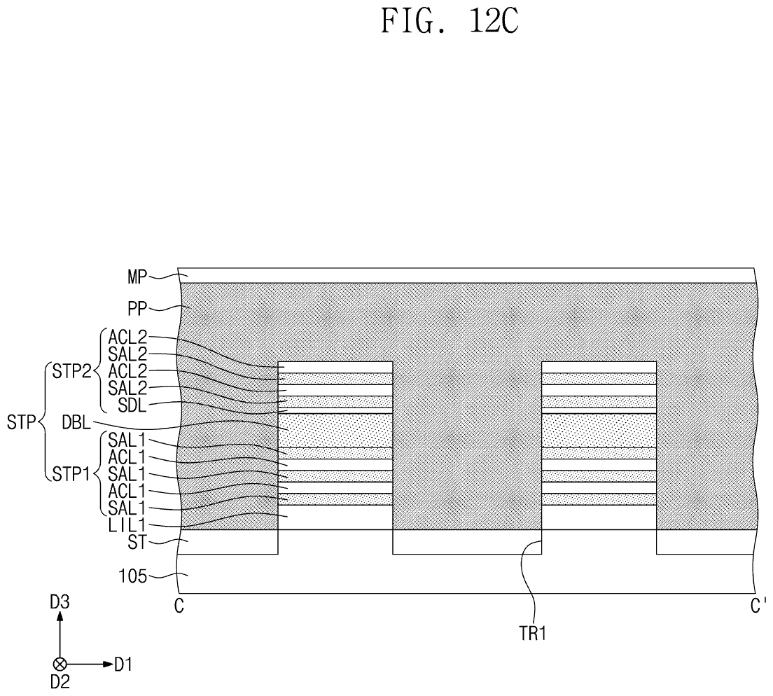

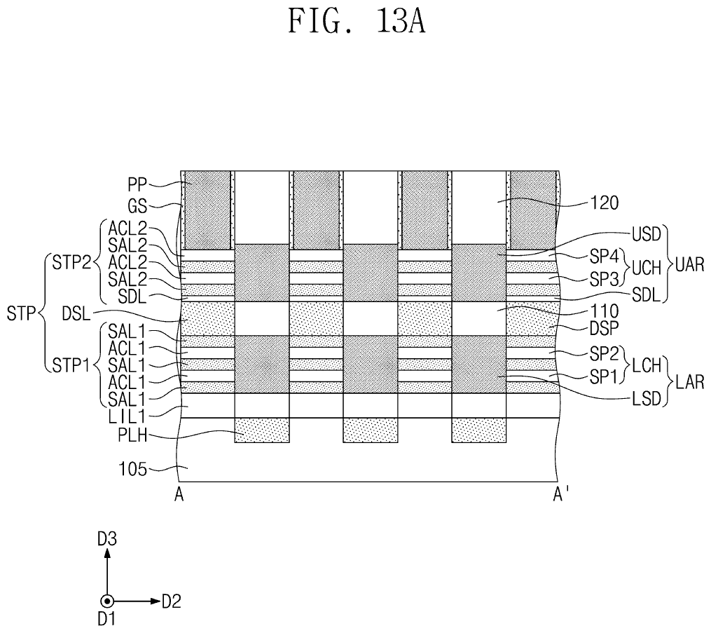

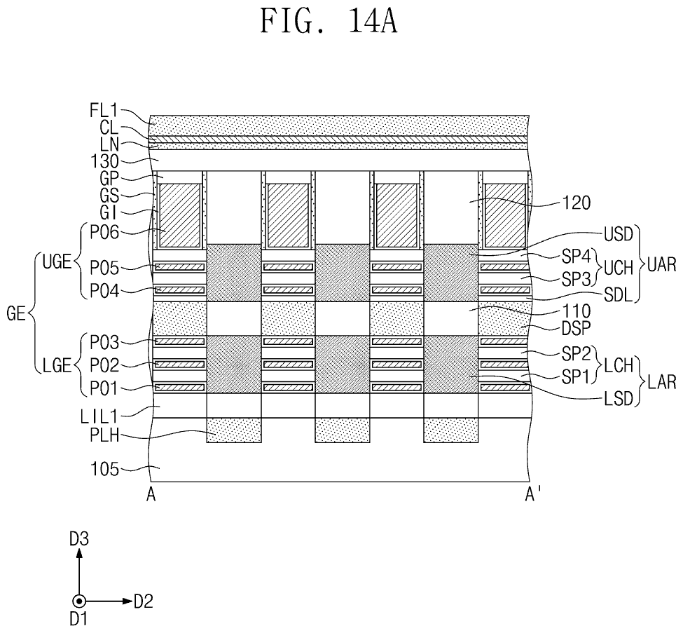

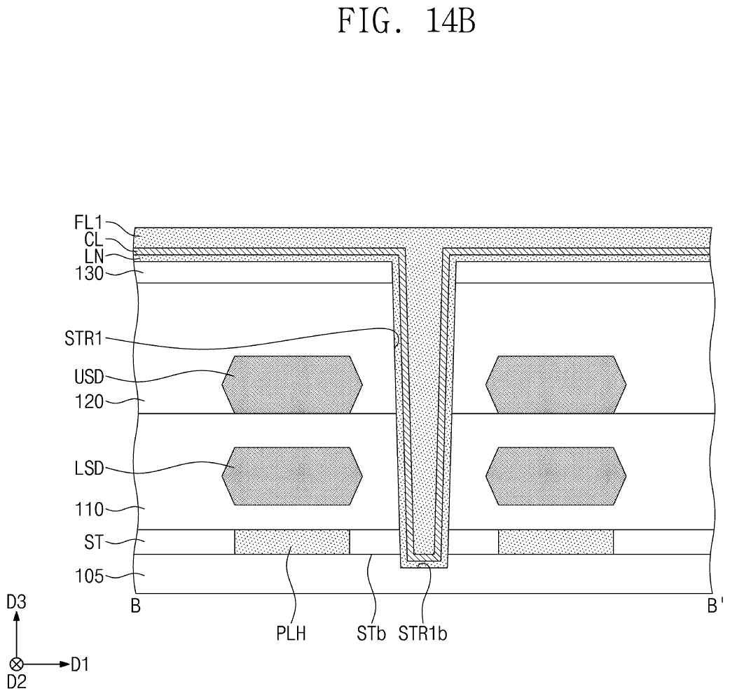

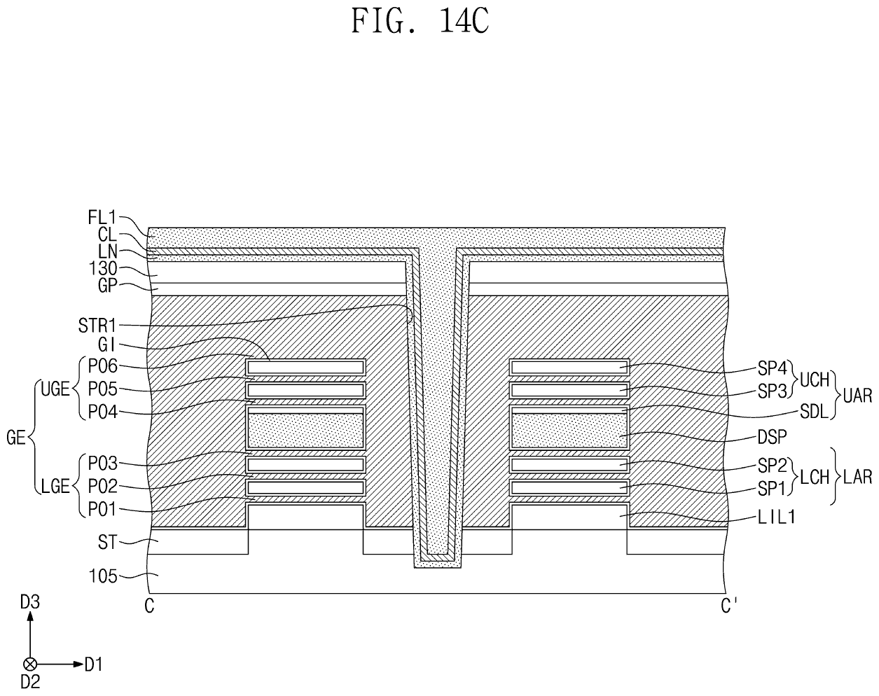

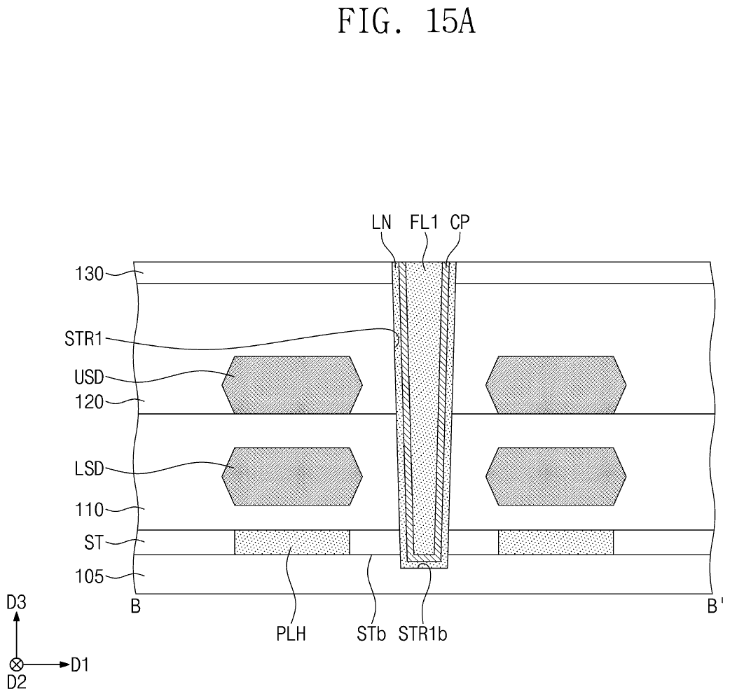

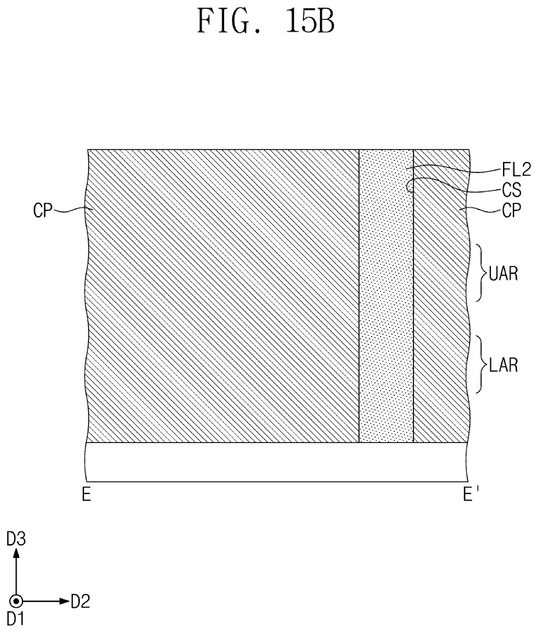

FIGS. 11A, 11B, 12A to 12C, 13A, 13B, 14A to 14C, 15A and 15B are cross-sectional views for explaining a method of manufacturing a three-dimensional semiconductor device according to embodiments of the inventive concept. In detail, FIGS. 11A, 12A, 13A, and 14A are sectional views taken along line A-A′ of FIG. 3, respectively. FIGS. 11B, 12B, 13B, 14B, and 15A are sectional views taken along line B-B′ in FIG. 3, respectively. FIGS. 12C and 14C are cross-sectional views taken along line C-C′ of FIG. 3, respectively. FIG. 15B is a cross-sectional view taken along line E-E′ of FIG. 3.

Hereinafter, a method of manufacturing a three-dimensional semiconductor device according to embodiments of the inventive concept will be described. To simplify the explanation, descriptions of content that overlap with the above-mentioned content are omitted.

Referring to FIGS. 3, 11A, and 11B, a semiconductor substrate 105 may be provided. The semiconductor substrate 105 may include any one of silicon (Si), germanium (Ge), and silicon-germanium (SiGe). For example, the semiconductor substrate 105 may be a single crystal silicon wafer.

A first lower insulating layer LIL1 may be formed on the semiconductor substrate 105. First sacrificial layers SAL1 and first active layers ACL1 may be alternately stacked on the first lower insulating layer LIL1. The first sacrificial layers SAL1 may include one of silicon (Si), germanium (Ge), and silicon germanium (SiGe), and the first active layers ACL1 may include the other one of silicon (Si), germanium (Ge) and silicon germanium (SiGe). For example, the first sacrificial layers SAL1 may include silicon germanium (SiGe), and the first active layers ACL1 may include silicon (Si).

A separation layer DSL may be formed on the uppermost first sacrificial layer SAL1. For example, a thickness of the separation layer DSL may be greater than a thickness of the first sacrificial layer SAL1. The separation layer DSL may include silicon (Si) or silicon germanium (SiGe). In an embodiment, the separation layer DSL includes silicon germanium (SiGe), and a concentration of germanium (Ge) in the separation layer DSL may be greater than a concentration of germanium (Ge) in the first sacrificial layer SAL1.

A seed layer SDL may be formed on the separation layer DSL. The seed layer SDL may include the same material as the first active layer ACL1. Second sacrificial layers SAL2 and second active layers ACL2 may be alternately stacked on the seed layer SDL. Each of the second sacrificial layers SAL2 may include the same material as the first sacrificial layer SAL1, and each of the second active layers ACL2 may include the same material as the first active layer ACL1. The separation layer DSL may be interposed between the first sacrificial layer SAL1 and the seed layer SDL.

The stacked first and second sacrificial layers SAL1 and SAL2, the first and second active layers ACL1 and ACL2, and the separation layer DSL may be patterned to form a stacked pattern STP. Forming the stacked pattern STP may include forming a hard mask pattern on the uppermost second active layer ACL2 and etching the layers SAL1, SAL2, ACL1, ACL2, SDL, and DSL stacked on the semiconductor substrate 105 using the hard mask pattern as an etch mask. While the stacked pattern STP is formed, an upper portion of the semiconductor substrate 105 may be patterned to form a first trench TR1 defining a region for a device isolation layer ST. The stacked pattern STP may have a bar shape or a line shape extending in the second direction D2.

The stacked pattern STP may include a lower stacked pattern STP1 on the first lower insulating layer LIL1, an upper stacked pattern STP2 on the lower stacked pattern STP1, and the separation layer DSL between the lower and upper stacked patterns STP1 and STP2. The lower stacked pattern STP1 may include the first sacrificial layers SAL1 and the first active layers ACL1 that are alternately stacked. The upper stacked pattern STP2 may include the seed layer SDL, and include the second sacrificial layers SAL2 and the second active layers ACL2 alternately stacked on the seed layer SDL. On the semiconductor substrate 105, a device isolation layer ST may be formed to fill the first trench TR1.

Referring to FIGS. 3 and 12A to 12C, a plurality of sacrificial patterns PP may be formed across the stacked pattern STP. Each sacrificial pattern PP may be formed in a line shape extending in the first direction D1. Specifically, forming the sacrificial pattern PP may include forming a sacrificial layer on the entire surface of the semiconductor substrate 105, forming a hard mask pattern MP on the sacrificial layer, and patterning the sacrificial layer using the hard mask pattern MP as an etch mask. The sacrificial layer may include amorphous silicon and/or polysilicon. A pair of gate spacers GS may be formed on both sidewalls of the sacrificial pattern PP, respectively.

An etching process may be performed on the stacked pattern STP using the gate spacers GS and the hard mask pattern MP as an etch mask. Through the etching process, a second trench TR2 may be formed between adjacent sacrificial patterns PP.

Sacrificial contact patterns PLH may be formed in the semiconductor substrate 105 exposed through the second trench TR2. The sacrificial contact patterns PLH may be arranged in the first and second directions D1 and D2, repeatedly. The sacrificial contact patterns PLH may include a material that has etch selectivity to the semiconductor substrate 105, for example, silicon-germanium (SiGe). The sacrificial contact patterns PLH may be formed using an epitaxial growth process. The second trench TR2 may expose the sacrificial contact pattern PLH.

In an embodiment of the invention, the separation layer DSL may include silicon germanium (SiGe), and the separation layer DSL may be replaced with a silicon-based insulating material. For example, the separation layer DSL exposed by the second trench TR2 may be selectively removed, and a silicon-based insulating material (e.g., silicon nitride) may be filled in the region where the separation layer DSL is removed.

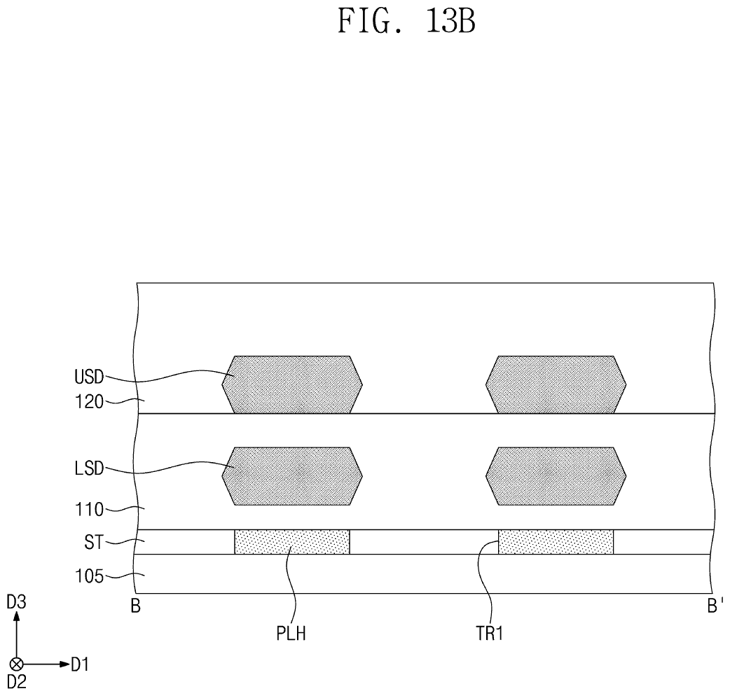

Referring to FIGS. 3, 13A, and 13B, a lower source drain pattern LSD may be formed in the second trench TR2. Specifically, the lower source drain pattern LSD may be formed by performing a first SEG process using the exposed sidewall of the lower stacked pattern STP1 as a seed layer through the second trench TR2.

During the first SEG process, impurities may be introduced in-situ into the lower source drain pattern LSD. As another example, after the lower source drain pattern LSD is formed, impurities may be injected into the lower source drain pattern LSD. The lower source drain pattern LSD may be doped to have a first conductivity type.

The first active layers ACL1 interposed between a pair of lower source drain patterns LSD may constitute a lower channel pattern LCH. For example, first and second semiconductor patterns SP1 and SP2 of the lower channel pattern LCH may be constituted from the first active layers ACL1. The lower channel patterns LCH and lower source drain patterns LSD may constitute a lower active region LAR, which is a lower tier of a three-dimensional device.

A first interlayer insulating layer 110 may be formed to cover the lower source drain pattern LSD. As an example, prior to forming the first interlayer insulating layer 110, an etch stop layer may be further formed to conformally cover the lower source drain pattern LSD. For example, the first interlayer insulating layer 110 may be a composite layer including a plurality of sub insulating layers. Prior to forming the lower source drain pattern LSD, a sub insulating layer of the first interlayer insulating layer 110 may be formed below the lower source drain pattern LSD, and after forming the lower source drain pattern LSD, another insulating layer of the first interlayer insulating layer 110 may be further formed.

An upper source drain pattern USD may be formed on the sidewall of the upper stacked pattern STP2. Specifically, the upper source drain pattern USD may be formed by performing a second SEG process using the exposed sidewall of the upper stacked pattern STP2 as a seed layer through the second trench TR2. The upper source drain pattern USD may be doped to have a second conductivity type different from the first conductivity type.

The second active layer ACL2 interposed between a pair of upper source drain patterns USD may constitute an upper channel pattern UCH. For example, third and fourth semiconductor patterns SP3 and SP4 of the upper channel pattern UCH may be constituted from the second active layers ACL2. The upper channel patterns UCH and upper source drain patterns USD may constitute the upper active region UAR, which is an upper tier of the three-dimensional device.

A second interlayer insulating layer 120 may be formed to cover the upper source drain pattern USD. As an example, prior to forming the second interlayer insulating layer 120, an etch stop layer may be further formed to conformally cover the upper source drain pattern USD.

Thereafter, the second interlayer insulating layer 120 may be planarized until an upper surface of the sacrificial pattern PP is exposed. During the planarization process, all hard mask patterns MP on the sacrificial pattern PP may be removed.

Referring to FIGS. 3 and 14A to 14C, the exposed sacrificial pattern PP may be selectively removed. By removing the sacrificial pattern PP, the first and second sacrificial layers SAL1 and SAL2 may be exposed.

An etching process may be performed to selectively etch the first and second sacrificial layers SAL1 and SAL2 while leaving the first to fourth semiconductor patterns SP1 to SP4 and a dummy channel pattern DSP intact while the removing.

A gate insulating layer GI may be conformally formed in a region where the sacrificial pattern PP and the first and second sacrificial layers SAL1 and SAL2 have been removed. Preliminary gate electrodes (not shown) may be formed on the gate insulating layer GI. The preliminary gate electrodes may include first to fifth preliminary inner electrodes PO1 to PO5 between the first to fourth semiconductor patterns SP1 to SP4, and the outer electrode PO6 in the region where the sacrificial pattern PP has been removed.

A gate capping pattern GP may be formed to cover an upper surface of the outer electrode PO6 of the preliminary gate electrodes. A third interlayer insulating layer 130 may be formed to cover the gate capping pattern GP and the second interlayer insulating layer 120.

A first separation trench STR1 may be formed to cross the preliminary gate electrode in the second direction D2. Accordingly, the preliminary gate electrode extending in the first direction D1 may be separated into intermediate gate electrodes GE spaced apart from each other in the first direction D1. The first separation trench STR1 may be formed to extend to a level lower than the lowermost surface STb of the device isolation layer ST. Accordingly, the lowermost surface STR1b of the first separation trench STR1 may be positioned at a lower level than the lowermost surface STb of the device isolation layer ST.

A preliminary liner insulating layer LN and a preliminary conductive plate layer CL may be formed to sequentially cover sidewalls of the first separation trench STR1 and an upper surface of the third interlayer insulating layer 130. Thereafter, a first preliminary filling pattern FL1 may be formed to fill the remainder of the first separation trench STR1 and cover the upper surface of the third interlayer insulating layer 130. As an example, although not shown in the drawings, when forming the first preliminary filling pattern FL1, the air gap AG, described with reference to FIG. 6, may be formed in the first preliminary filling pattern FL1.

Referring to FIGS. 3, 15A, and 15B, a planarization process may be performed on the preliminary liner insulating layer LN, the preliminary conductive plate layer CL, and the first preliminary filling pattern FL1, thereby forming an intermediate liner insulating layer LN, an intermediate conductive plate CP, and a first intermediate filling patterns FL1 that are adjacent to each other in the first direction D1 with each extending in the second direction D2. In each of the first separation trenches STR1, a portion of the intermediate liner insulating layer LN and a portion of the first intermediate filling pattern FL1 may constitute a first separation insulating pattern SI1 (in the final product).

Though not shown in the drawings, a second separation trench STR2 (in FIGS. 3, 4, 5A to 5E) may be formed to cross the intermediate gate electrode GE in the second direction D2. Accordingly, the intermediate gate electrode GE extending in the first direction D1 may be separated into gate electrodes GE spaced apart from each other in the first direction D1. Thereafter, a second separation insulating pattern SI2 may be formed to fill the second separation trench STR2. Though the second separation trench STR2 is shown to be formed through an additional process from the first separation trench STR1, the inventive concept is not limited thereto. As another example, the first and second separation trenches STR1 and STR2 may be formed simultaneously.

A second filling pattern FL2 may be formed in the conductive separation region CS.

Again, referring to FIGS. 3, 4, 5A to 5E, upper active contacts UAC may be formed through the second and third interlayer insulating layers 120 and 130 and respectively connected to the upper source drain patterns USD. An upper gate contact UGC may be formed that penetrates the second and third interlayer insulating layers 120 and 130 and is electrically connected to the gate electrode GE.

A fourth interlayer insulating layer 140 may be formed on the third interlayer insulating layer 130. A first metal layer M1 including upper interconnections UMI may be formed in the fourth interlayer insulating layer 140. Upper vias UVI may be formed to electrically connect the first metal layer M1 to the gate contacts GC and the upper active contacts UAC. A BEOL layer including additional metal layers (e.g., M2, M3, M4, etc.) may be formed on the first metal layer M1. As an example, a first upper contact UCa may be formed to extend from an upper surface of the upper source drain pattern USD to an upper surface of the intermediate conductive plate CP. As an example, a second upper contact UCb may be formed on an upper surface of intermediate conductive plate CP.

Thereafter, though not shown in the drawings, the semiconductor substrate 105 may be turned over so that the back surface of the semiconductor substrate 105 is exposed. The exposed semiconductor substrate 105 may be selectively removed. As a result, the sacrificial contact patterns PLH and the first lower insulating layer LIL1 may be exposed. In an embodiment, a lower portion of the intermediate conductive plate CP may be also removed during the selective removing of the semiconductor substrate 105, and intermediate conductive plate CP may be separated into a first conductive plate CP1 and a second conductive plate CP2 that are adjacent to each other in the first direction D1. Likewise, one intermediate liner insulating layers LN conformally covering the sidewall of the first separation trench STR1 may be separated into a pair of liner insulating layers LN adjacent to each other in the first direction D1.

A removal process may be performed on a portion of the conductive plates CP and a portion of the first separation insulating pattern SI1, thereby forming a conductive isolation region CS in the first separation insulating pattern SI1.

The conductive plates CP1 and CP2 may form different electrical nodes and not be electrically connected to each other (at least not directly such that they would form a single electrical node). The conductive plates CP1 and CP2 may be electrically isolated from one another such that they may carry different electrical signals from one another.

According to an embodiment of the inventive concept, the intermediate conductive plates CP may be formed to conformally cover the first separation trench STR1 on the intermediate liner insulating layer LN. Without an additional photolithography process, the preliminary conductive plate layer CL (and the intermediate conductive plate CP) is separated into the plurality of conductive plates CP. Accordingly, the conductive plate CP may be easily formed and confined in the first separation trench STR1 without being misaligned. As a result, the conductive plate CP may not be in undesirable contact with (e.g., electrically shorted to) any neighboring components including conductive materials. In addition, as a photolithography process is not involved, there may be no need to manufacture an additional mask according to the photolithography process. Therefore, productivity of three-dimensional semiconductor devices may be improved.

In addition, the conductive plate CP may be formed to conformally cover the first separation trench STR1 on the liner insulating layer LN, and thus a seam or void may not be formed in the conductive plate CP. Accordingly, electrical resistance of the conductive plate CP may be reduced. As a result, electrical characteristics of the three-dimensional semiconductor device may be improved.

A second lower insulating layer LIL2 may be formed on the exposed sacrificial contact patterns PLH and the exposed first lower insulating layer LIL1. A planarization process may be performed on the second lower insulating layer LIL2 until the sacrificial contact patterns PLH are exposed.

The sacrificial contact pattern PLH may be replaced with a lower active contact LAC. Specifically, the sacrificial contact pattern PLH may be selectively removed. An etching process may be further performed on the region from which the sacrificial contact pattern PLH was removed to expose the lower source drain pattern LSD. The lower active contact LAC connected to the exposed lower source drain pattern LSD may be formed. The lower active contact LAC may be formed using a self-alignment manner using a sacrificial contact pattern PLH. A lower gate contact LGC may be formed that penetrates the first lower insulating layer LIL1 and is electrically connected to the gate electrode GE.

A backside metal layer BSM may be formed on the lower active contact LAC. The backside metal layer BSM may include a lower contact LC, a lower interconnection LMI, and a lower via LVI. Additional backside metal layers may be formed on the backside metal layer BSM. In one embodiment of the invention, additional backside metal layers may include a power transmission network.

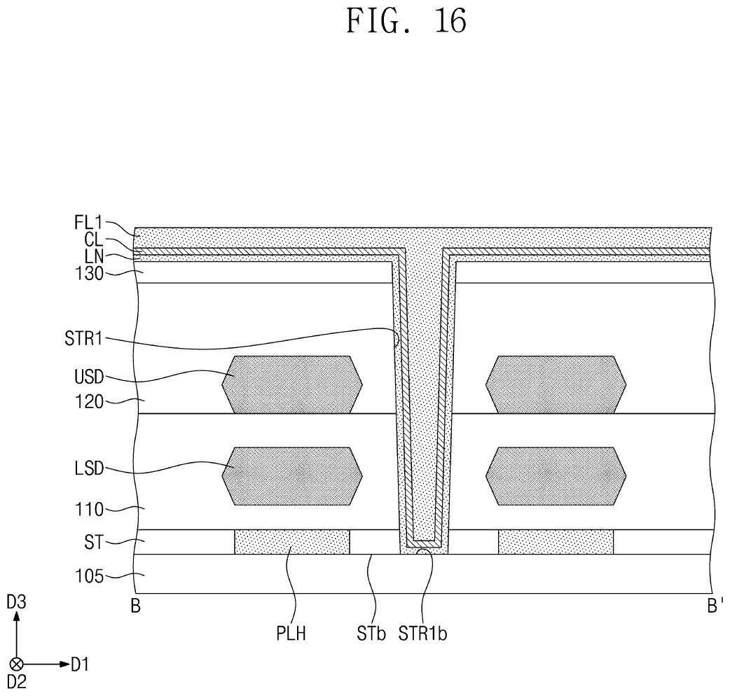

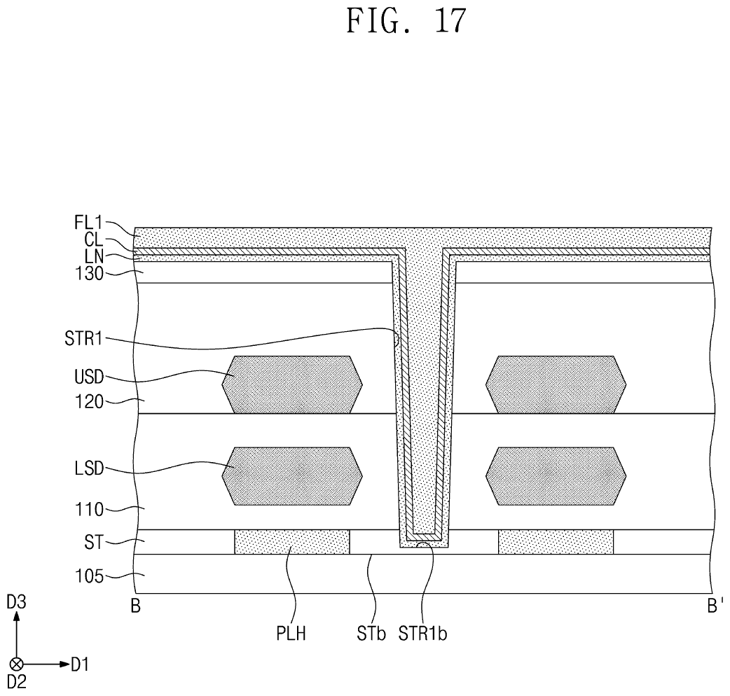

FIGS. 16 and 17 are cross-sectional views for explaining a method of manufacturing a three-dimensional semiconductor device according to embodiments of the inventive concept. More specifically, FIGS. 16 and 17 are each cross-sectional views taken along line B-B′ of FIG. 3.

First, referring to FIGS. 3 and 16, during forming the first separation trench STR1 described with reference to FIGS. 14A to 14C, the first separation trench STR1 may be formed to extend to substantially the same level as the lowermost surface STb of the device isolation layer ST. Accordingly, the lowermost end STR1b of the first separation trench STR1 may be positioned at substantially the same level as the lowermost surface STb of the device isolation layer ST.

Thereafter, the three-dimensional semiconductor device described with reference to FIGS. 3, 4, 5A to 5E may be formed using the semiconductor device manufacturing method, which is the same as or similar to that described above.

Referring to FIGS. 3 and 17, during forming the first separation trench STR1 described with reference to FIGS. 14A to 14C, the first separation trench STR1 may be formed to extend to a level higher than the lowermost surface STb of the device isolation layer ST. Specifically, the lowermost end STR1b of the first separation trench STR1 may be formed to be positioned between the upper and lower surfaces of the sacrificial contact pattern PLH. Accordingly, the lowermost surface STR1b of the first separation trench STR1 may be positioned at a higher level than the lowermost surface STb of the device isolation layer ST.

Thereafter, the three-dimensional semiconductor device described with reference to FIGS. 3, 4, 5A to 5E may be formed using the semiconductor device manufacturing method, which is the same as or similar to that described above.

According to embodiments of the inventive concept, the first and second conductive plates adjacent to each other in the first direction may be provided in one first separation trench. Accordingly, the source drain pattern of each of the two single height cells and the neighboring components (e.g., the backside metal layer and the first metal layer) may be electrically connected to at least one of the two conductive plates provided in the one separation trench. As a result, the integration and the design freedom of the three-dimensional semiconductor device may be improved.

According to the inventive concept, the conductive plate may be formed to conformally cover the first separation trench on the liner insulating layer. Accordingly, the conductive plate may be easily formed in the first separation trench without being misaligned. As a result, the conductive plate may not be undesirably electrically shorted of the neighboring components including the conductive materials. Therefore, the productivity of three-dimensional semiconductor devices may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A three-dimensional semiconductor device comprising:
a backside metal layer;
first lower channel patterns and first upper channel patterns sequentially provided on the backside metal layer;
first gate electrodes crossing the first lower channel patterns and the first upper channel patterns;
second gate electrodes adjacent to the first gate electrodes in a first direction;
a separation insulating pattern between the first and second gate electrodes;
a first conductive plate extending in the separation insulating pattern in each of a second direction and a third direction; and
a second conductive plate extending in the separation insulating pattern in each of the second direction and the third direction, the second conductive plate adjacent to the first conductive plate in the first direction,
wherein the first conductive plate and the second conductive plate are separated from each other.

2. The three-dimensional semiconductor device of claim 1, wherein a width of the first conductive plate in the first direction is substantially the same along the third direction.

3. The three-dimensional semiconductor device of claim 1, wherein a distance between the first conductive plate and the second conductive plate decreases with respect to a downward direction.

4. The three-dimensional semiconductor device of claim 1, wherein the first conductive plate and the second conductive plate are symmetrical with respect to each other when viewed in a cross-sectional view.

5. The three-dimensional semiconductor device of claim 1, wherein the separation insulating pattern includes an air gap between the first conductive plate and the second conductive plate.

6. The three-dimensional semiconductor device of claim 1, wherein the separation insulating pattern includes:
a first liner insulating layer between the first gate electrodes and the first conductive plate,
a second liner insulating layer between the second gate electrodes and the second conductive plate, and
a filling pattern between the first conductive plate and the second conductive plate.

7. The three-dimensional semiconductor device of claim 1, wherein the first conductive plate includes a recess region on at least one of an upper portion and a lower portion thereof.

8. The three-dimensional semiconductor device of claim 1, further comprising a third conductive plate and a fourth conductive plate,
wherein:
the third conductive plate is spaced apart from the first conductive plate in the second direction,
the fourth conductive plate is spaced apart from the second conductive plate in the second direction, and
the first, second, third and fourth conductive plates are electrically separated from each other.

9. The three-dimensional semiconductor device of claim 1, further comprising a second separation insulating pattern, wherein:
the separation insulating pattern is a first separation insulating pattern
the first and second separation insulating patterns are adjacent to each other in the first direction, and
the first conductive plate is provided in the first separation insulating pattern.

10. The three-dimensional semiconductor device of claim 9, wherein, in the first direction, a width of an upper surface of the second separation insulating pattern is smaller than a width of an upper surface of the first separation insulating pattern.

11. The three-dimensional semiconductor device of claim 1, further comprising:
a first lower source drain pattern and a second lower source drain pattern spaced apart from each other in the second direction; and
a first upper source drain pattern on the first lower source drain pattern and a second upper source drain pattern on the second lower source drain pattern,
wherein:
the first lower channel patterns are interposed between the first lower source drain pattern and the second lower source drain pattern, and
the first conductive plate is electrically connected to one of the first lower source drain pattern, the second lower source drain pattern, the first upper source drain pattern, and the second upper source drain pattern.

12. A three-dimensional semiconductor device comprising:
a backside metal layer;
first lower channel patterns and first upper channel patterns sequentially provided on the backside metal layer;
second lower channel patterns and second upper channel patterns sequentially provided on the backside metal layer;
first gate electrodes crossing the first lower channel patterns and the first upper channel patterns;
second gate electrodes crossing the second lower channel patterns and the second upper channel patterns, the second gate electrodes adjacent to the first gate electrodes in a first direction;
a separation insulating pattern between the first and second gate electrodes;
a first conductive plate extending in the separation insulating pattern in each of a second direction and a third direction, the first conductive plate adjacent to the first gate electrodes; and
a second conductive plate extending in the separation insulating pattern in each of the second direction and the third direction, the second conductive plate adjacent to the second gate electrodes,
wherein:
the first conductive plate and the second conductive plate are separate from each other, and
the first, second and third second directions are perpendicular to each other.

13. The three-dimensional semiconductor device of claim 12, wherein the first conductive plate and the second conductive plate are adjacent to each other in the first direction.

14. The three-dimensional semiconductor device of claim 12, wherein a distance between the first conductive plate and the second conductive plate decreases with respect to a downward direction.

15. The three-dimensional semiconductor device of claim 12, wherein a width of the first conductive plate in the first direction is substantially the same along the third direction.

16. The three-dimensional semiconductor device of claim 12, wherein the first conductive plate and the second conductive plate are symmetrical with respect to each other when viewed in a cross-sectional view.

17. The three-dimensional semiconductor device of claim 12, wherein a distance between the first conductive plate and the first gate electrodes in the first direction is substantially the same along the third direction.

18. A three-dimensional semiconductor device comprising:
a backside metal layer;
first lower channel patterns and first upper channel patterns sequentially provided on the backside metal layer;
second lower channel patterns and second upper channel patterns sequentially provided on the backside metal layer;
first gate electrodes crossing the first lower channel patterns and the first upper channel patterns;
second gate electrodes crossing the second lower channel patterns and the second upper channel patterns, the second gate electrodes adjacent to the first gate electrodes in a first direction;
a separation insulating pattern between the first and second gate electrodes;
a first conductive plate extending in the separation insulating pattern in each of a second direction and a third direction; and
a second conductive plate extending in the separation insulating pattern in each of the second direction and the third direction, the second conductive plate adjacent to the first conductive plate in the first direction,
wherein:
the first conductive plate and the second conductive plate are separate from each other, and
the first, second and third second directions are perpendicular to each other.

19. The three-dimensional semiconductor device of claim 18, wherein a width of the first conductive plate in the first direction is substantially the same along the third direction.

20. The three-dimensional semiconductor device of claim 18, wherein a distance between the first conductive plate and the second conductive plate decreases with respect to a downward direction.
